(19) United States
(12) Patent Application Publication
(10) Pub. No.: US 2026/0288205 A1
(43) Pub. Date: Sep. 24, 2026

(54) ELECTRONIC APPARATUS AND METHOD FOR MANUFACTURING THE ELECTRONIC APPARATUS

(71) Applicant: Samsung Display Co., Ltd., Yongin-si (KR)

(72) Inventors: JIHYE LIM, Yongin-si (KR); HYEIN YANG, Yongin-si (KR); Eunhee NAM, Yongin-si (KR); HYUNSOOK KIM, Yongin-si (KR); CHANG WOO LEE, Yongin-si (KR); GISUK KWON, Yongin-si (KR); YOUNGMOON KIM, Yongin-si (KR)

(21) Appl. No.: 19/443,290

(22) Filed: Jan. 8, 2026

(30) Foreign Application Priority Data
Mar. 19, 2025 (KR) 10-2025-0035194

(51) Int. Cl. G06F 1/16

(52) U.S. Cl. CPC G06F 1/1656; G06F 1/1618; G06F 1/1641

(57) ABSTRACT

An electronic apparatus including a display module and a window member, and a method for manufacturing the electronic apparatus. The display module includes a folding part, a first non-folding part adjacent to one side of the folding part, and a second non-folding part adjacent to the other side of the folding part. The window member includes a glass substrate and a polymer layer. The polymer layer is disposed on at least one of the lower surface or the upper surface of the glass substrate, and includes a polymer derived from a resin composition. The resin composition includes a polyisocyanate, a polyol, an acrylate containing a cycloalkyl group, and a photoinitiator.

### CROSS-REFERENCE TO RELATED APPLICATIONS

This U.S. non-provisional patent application is based on and claims priority to Korean Patent Application No. 10-2025-0035194, filed in the Korean Intellectual Property Office on Mar. 19, 2025, and all the benefits accruing therefrom under 35 U.S.C. § 119, the content of which in its entirety is hereby incorporated by reference.

### BACKGROUND

The present disclosure herein relates to an electronic apparatus including a polymer layer disposed on a glass substrate and a method for manufacturing the electronic apparatus.

Various electronic apparatuses such as televisions, mobile phones, tablet computers, and game consoles are being developed. Recently, flexible electronic apparatuses including flexible display panels capable of folding, rolling, or sliding have been developed. Unlike rigid electronic apparatuses, flexible electronic apparatuses may be folded, or rolled. Flexible electronic apparatuses whose shapes may be changed in various ways may be carried regardless of the existing screen size, thereby improving user convenience. Flexible electronic apparatuses require members (e.g., components, or parts) to maintain flexible operation reliability.

### SUMMARY

An object of the present disclosure is to provide an electronic apparatus exhibiting excellent folding reliability, excellent impact resistance, and excellent display quality.

Another object of the present disclosure is to provide a method for manufacturing an electronic apparatus that exhibits excellent manufacturing efficiency and excellent processability.

An embodiment provides an electronic apparatus including a display module including a folding part, a first non-folding part adjacent to one side of the folding part, and a second non-folding part adjacent to the other side of the folding part, and a window member disposed on the display module, where the window member includes a glass substrate including a lower surface and an upper surface facing the lower surface in a thickness direction, and a polymer layer disposed on at least one of the lower surface or the upper surface, and including a polymer derived from a resin composition. The resin composition includes a polyisocyanate, a polyol, an acrylate including a cycloalkyl group, and a photoinitiator.

In an embodiment, the polymer layer may have a hardness of about 1.0 megapascal (MPa) or more and about 10.0 MPa or less, an elastic modulus of about 10 MPa or more and about 300 MPa or less, an indentation depth of about 1.0 micrometer (μm) or more and about 5.0 μm or less, and a creep value of about 2.0% or more and about 150.0% or less, and the hardness, the elastic modulus, the indentation depth, and the creep value may be measured by a nano indentation tester at temperatures of about −5° C. and about 25° C.

In an embodiment, the polyisocyanate may include at least one of methylene diphenyl diisocyanate (MDI), hexamethylene diisocyanate, or isophorone diisocyanate. Optionally, a polycaprolactone (PCL) may be present. The acrylate may include isobornyl acrylate (IBOA), and the photoinitiator may include at least one of 1-hydroxy cyclohexyl-phenyl ketone or N,N,N′,N′-tetramethyl methanediamine.

In an embodiment, the polyol of the resin composition may include a polymeric polyol, and the polymeric polyol may include at least one of a polyether polyol such as polytetramethylene ether glycol (PTMEG) or polypropylene glycol (PPG).

In an embodiment, the resin composition may further include at least one of an organic catalyst, a plasticizer, an antioxidant, and a coupling agent. The plasticizer may include a material represented by any one of X-1 to X-5, and the antioxidant may include a material represented by Y—. The coupling agent may include at least one of a silane-containing coupling agent or a phosphoric acid-containing coupling agent.

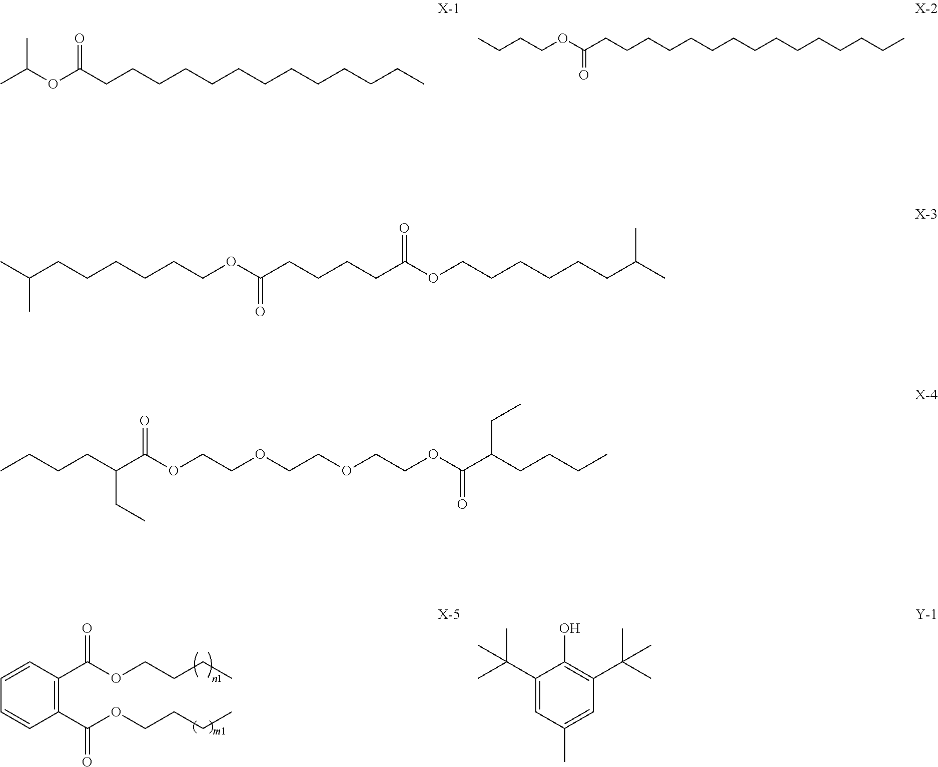

In X-5, n1 and ml are each independently an integer of 1 to 10.

In an embodiment, the resin composition may further include at least one of first to sixteenth monomers represented by A-1 to A-16, respectively.

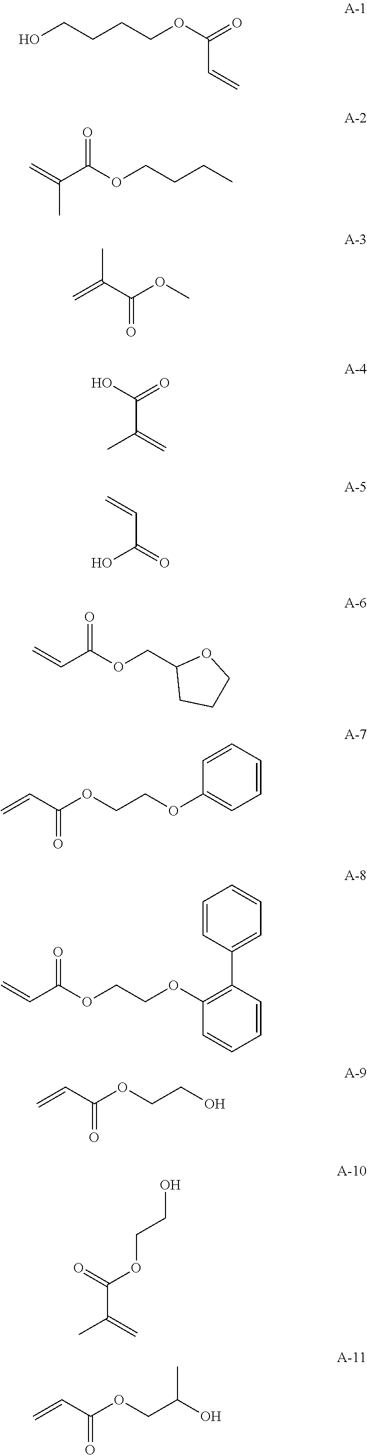

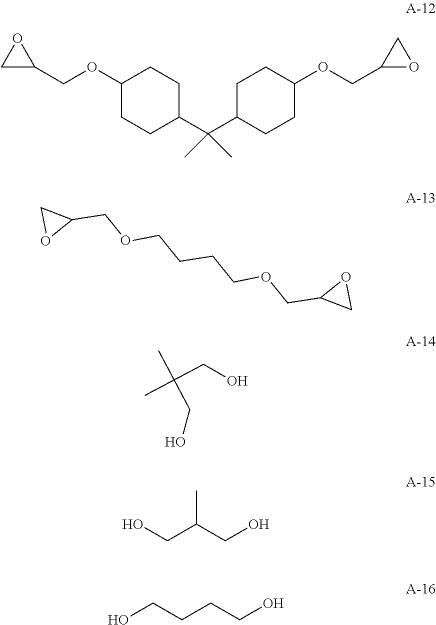

In an embodiment, a difference between a refractive index of the glass substrate and a refractive index of the polymer layer may be about 0.3 or less.

In an embodiment, the window member may further include an adhesive layer directly disposed on one surface of the polymer layer spaced apart from the glass substrate.

In an embodiment, the glass substrate may include a side surface disposed between the upper surface and the lower surface, and the polymer layer may surround at least one of the upper surface, the lower surface, or the side surface.

In an embodiment, the glass substrate may be divided into a first portion overlapping the folding part, a second portion overlapping the first non-folding part, and a third portion overlapping the second non-folding part, and a thickness of the first portion may be smaller than a thickness of the second portion and a thickness of the third portion.

In an embodiment, the polymer layer may be divided into a fourth portion overlapping the folding part, a fifth portion overlapping the first non-folding part, and a sixth portion overlapping the second non-folding part, and a thickness of the fourth portion may be greater than a thickness of the fifth portion and a thickness of the sixth portion.

In an embodiment, the electronic apparatus may further include at least one of a processor, a power module, or a memory.

Another embodiment provides a method for manufacturing an electronic apparatus, including preparing a display module including a folding part, a first non-folding part adjacent to one side of the folding part, and a second non-folding part adjacent to the other side of the folding part, and providing a window member including a glass substrate including a lower surface and an upper surface facing the lower surface in a thickness direction, and a polymer layer disposed on at least one of the lower surface or the upper surface and including a polymer derived from a resin composition on the display module, where the resin composition includes a polyisocyanate, a polyol, an acrylate including a cycloalkyl group, and a photoinitiator, and the providing of the window member includes preparing the glass substrate, providing the resin composition on the glass substrate to form a preliminary polymer layer, and irradiating light on the preliminary polymer layer to form the polymer layer.

In an embodiment, in forming the polymer layer, plasma treatment may be performed on the polymer layer after irradiating the light.

In an embodiment, the resin composition may be provided by an inkjet printing method or a dispensing method.

In an embodiment, the polyisocyanate may include at least one of methylene diphenyl diisocyanate (MDI), hexamethylene diisocyanate, or isophorone diisocyanate. The acrylate may include isobornyl acrylate (IBOA), and the photoinitiator may include at least one of 1-hydroxycyclohexyl phenyl ketone or N,N,N′,N′-tetramethyl methanediamine. The resin composition may include polycaprolactone (PCL).

In an embodiment, a weight of the polyisocyanate may be about 1 weight percent (wt %) or more and about 10 wt % or less based on the total weight of the resin composition, and a weight of the acrylate may be about 50 wt % or more and about 80 wt % or less based on the total weight of the resin composition.

In an embodiment, the resin composition may include a polymeric polyol, and the polymeric polyol may include at least one of a polyether polyol such as polytetramethylene ether glycol (PTMEG) or polypropylene glycol (PPG).

In an embodiment, a weight of the polymeric polyol may be about 1 wt % or more and about 10 wt % or less based on the total weight of the resin composition.

In an embodiment, the resin composition may further include at least one of an organic catalyst, a plasticizer, an antioxidant, or a coupling agent. The plasticizer may include a material represented by any one of X-1 to X-5, and the antioxidant may include a material represented by Y-1. The coupling agent may include at least one of a silane-containing coupling agent or a phosphoric acid-containing coupling agent.

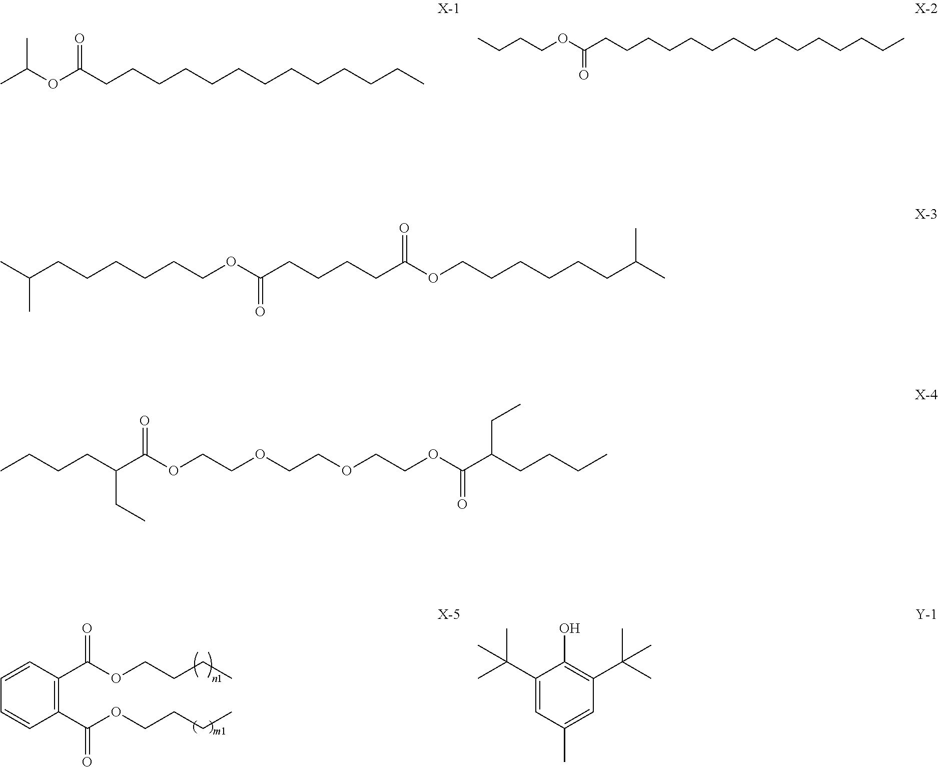

In X-5, n1 and ml are each independently an integer of 1 to 10.

### BRIEF DESCRIPTION OF THE FIGURES

The accompanying drawings are included to provide a further understanding of the inventive concept and are incorporated in and constitute a part of this specification. The drawings illustrate embodiments of the inventive concept and, together with the description, serve to explain principles of the inventive concept. In the drawings.

FIG. 1 is a block diagram of an electronic apparatus according to an embodiment;

FIG. 2 is a diagram showing electronic apparatuses according to various embodiments;

FIG. 3A is a perspective view showing an electronic apparatus of an embodiment;

FIG. 3B is a perspective view showing an electronic apparatus of an embodiment;

FIG. 3C is a plan view showing an electronic apparatus of an embodiment;

FIG. 3D is a perspective view showing an electronic apparatus of an embodiment;

FIG. 4A is a perspective view showing an electronic apparatus of an embodiment;

FIG. 4B is a perspective view showing an electronic apparatus of an embodiment;

FIG. 4C is a perspective view showing an electronic apparatus of an embodiment;

FIG. 5 is an exploded perspective view showing an electronic apparatus of an embodiment;

FIG. 6 is a cross-sectional view showing a portion corresponding to line I-I′ in FIG. 5;

FIG. 7A is a cross-sectional view showing a portion of an electronic apparatus of an embodiment;

FIG. 7B is a cross-sectional view showing a portion of an electronic apparatus of an embodiment;

FIG. 7C is a cross-sectional view showing a portion of an electronic apparatus of an embodiment;

FIG. 7D is a cross-sectional view showing a portion of an electronic apparatus of an embodiment;

FIG. 7E is a cross-sectional view showing a portion of an electronic apparatus of an embodiment;

FIG. 7F is a cross-sectional view showing a portion of an electronic apparatus of an embodiment;

FIG. 7G is a cross-sectional view showing a portion of an electronic apparatus of an embodiment;

FIG. 8 is a cross-sectional view showing a portion corresponding to line II-II′ in FIG. 5;

FIG. 9A is a flowchart showing a method for manufacturing an electronic apparatus of an embodiment;

FIG. 9B is a flowchart showing a method for manufacturing an electronic apparatus of an embodiment;

FIG. 10A is a diagram schematically showing a manufacturing step of an electronic apparatus of an embodiment;

FIG. 10B is a diagram schematically showing a manufacturing step of an electronic apparatus of an embodiment;

FIG. 10C is a diagram schematically showing a manufacturing step of an electronic apparatus of an embodiment;

FIG. 10D is a diagram schematically showing a manufacturing step of an electronic apparatus of an embodiment;

FIG. 10E is a diagram schematically showing a manufacturing step of an electronic apparatus of an embodiment;

FIG. 11A is a diagram schematically showing a manufacturing step of an electronic apparatus of an embodiment;

FIG. 11B is a diagram schematically showing a manufacturing step of an electronic apparatus of an embodiment;

FIG. 11C is a diagram schematically showing a manufacturing step of an electronic apparatus of an embodiment;

FIG. 11D is a diagram schematically showing a manufacturing step of an electronic apparatus of an embodiment;

FIG. 11E is a diagram schematically showing a manufacturing step of an electronic apparatus of an embodiment;

FIG. 11F is a diagram schematically showing a manufacturing step of an electronic apparatus of an embodiment;

FIG. 12A is a graph showing hardness (megapascals, MPa) in polymer layers of the Comparative Examples and Example;

FIG. 12B is a graph showing elastic modulus (megapascals, MPa) in polymer layers of the Comparative Examples and Example;

FIG. 12C is a graph showing indentation depths (micrometers, μm) in polymer layers of the Comparative Examples and Example; and

FIG. 12D is a graph showing creep values (percent, %) in polymer layers of the Comparative Examples and Example.

### DETAILED DESCRIPTION

The inventive concept may have various modifications and may be embodied in different forms, and example embodiments will be explained in detail with reference to the accompanying drawings. The inventive concept may, however, be embodied in different forms and should not be construed as limited to the embodiments set forth herein. Rather, all modifications, equivalents, and substituents which are included in the spirit and technical scope of the inventive concept should be included in the inventive concept.

In this specification, it will be understood that when an element (or a region, a layer, a portion, or the like) is referred to as being “on”, “connected to” or “coupled to” another element, it may be directly disposed on, connected to, or coupled to the other element, or other elements may be disposed therebetween.

Like reference numerals or symbols refer to like elements throughout. In the drawings, the thickness, ratio, and size of the elements are exaggerated for effectively describing the technical contents. As used herein, the term “and/or” includes any and all combinations of one or more of the associated listed elements.

It will be understood that, although the terms “first”, “second”, etc. may be used herein to describe various elements, the elements are not to be limited by these terms. These terms are only used to distinguish one element, component, region, layer or section from another element, component, region, layer or section. For instance, a first element, component, region, layer or section discussed below could be termed a second element, component, region, layer or section without departing from the scope of the inventive concept. Similarly, a second element, component, region, layer or section could be termed a first element, component, region, layer or section. In this specification, the singular expressions “a”, “an” and “the” are intended to include the plural forms as well, unless the context clearly indicates otherwise.

“At least one” is not to be construed as limiting “a” or “an.” “Or” means “and/or.” As used herein, the term “and/of” includes any and all combinations of one or more of the associated listed items.

In addition, the terms “below”, “under”, “on the lower side”, “above”, “over”, “on the upper side”, or the like may be used to describe the relationships between the elements illustrated in the drawings. These terms are relative concepts and are described on the basis of the directions indicated in the drawings.

It will be further understood that the terms “comprises, includes, has” and/or “comprising, including, having”, when used in this specification, specify the presence of stated features, numbers, steps, operations, elements, components or combinations thereof, but do not preclude the possibility of the presence or addition of one or more other features, numbers, steps, operations, elements, components, and/or combinations thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10%, ±5%, or ±3% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In the present specification, a cycloalkyl group may mean a cyclic alkyl group. The carbon atoms of the cycloalkyl group is 3 to 60, 3 to 50, 3 to 30, or 3 to 20, or 3 to 10. Examples of the cycloalkyl group include, but are not limited to, a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and the like.

Hereinafter, embodiments of the inventive concept will be described with reference to the drawings.

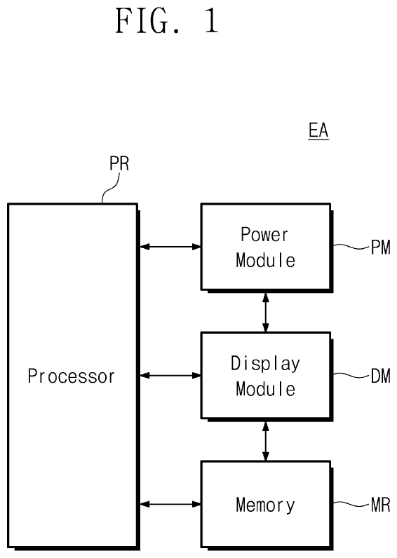

FIG. 1 is a block diagram of an electronic apparatus according to an embodiment. The electronic apparatus EA may include a display module DM. The electronic apparatus EA may further include at least one among a processor PR, a memory MR, and a power module PM. Referring to FIG. 1, the electronic apparatus EA according to an embodiment may include a display module DM, a processor PR, a memory MR, and a power module PM.

The processor PR may include at least one of a central processing unit (CPU), an application processor (AP), a graphic processing unit (GPU), a communication processor (CP), an image signal processor (ISP), or a controller.

The memory MR may store data information necessary for the operation of the processor PR or the display module DM. When the processor PR executes an application stored in the memory MR, an image data signal and/or an input control signal is transmitted to the display module DM, and the display module DM may process the received signal and output image information through a display screen.

The power module PM may include a power supply module such as a power adapter or a battery device, and a power conversion module that converts power supplied by the power supply module to generate power needed for the operation of the electronic apparatus EA.

At least one of the elements of the electronic apparatus EA described above may be included in a display device according to embodiments described below. In addition, some of individual modules functionally included in one module may be included in the display device, and other parts may be provided separately from the display device. For example, the display device may include the display module DM, and the processor PR, the memory MR, and the power module PM may be provided in the form of other devices within the electronic apparatus EA other than the display device.

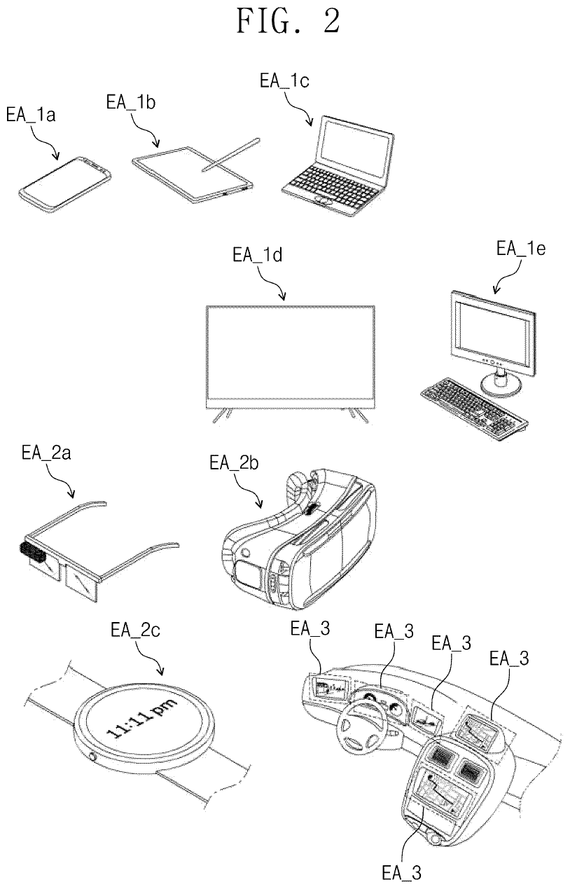

FIG. 2 is a schematic diagram of electronic apparatuses according to various embodiments. Referring to FIG. 2, various electronic apparatuses to which display devices according to embodiments are applied may include not only image display electronic apparatuses such as a smart phone EA_1a, a tablet PC EA_1b, a laptop EA_1c, a TV EA_1d, and a desk monitor EA_1e, but also wearable electronic apparatuses including display modules such as smart glasses EA_2a, a head-mounted display EA_2b, and a smart watch EA_2c, and vehicle electronic apparatuses EA_3 including display modules such as a dashboard, a center fascia, a Center Information Display (CID) placed on a dashboard, and a room mirror display of a car.

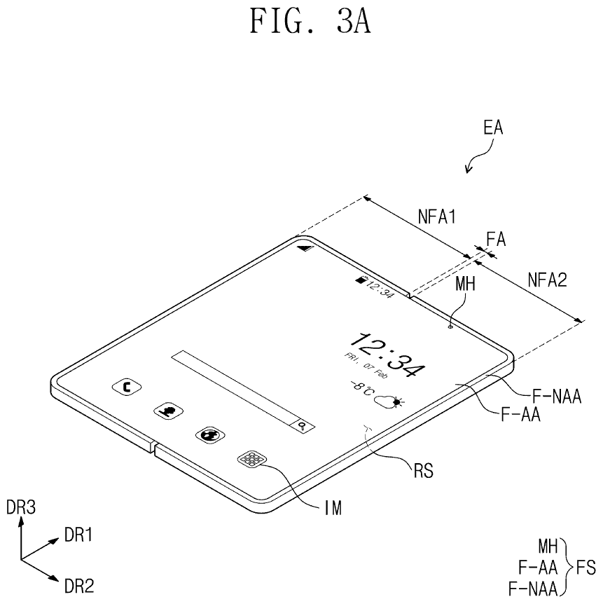

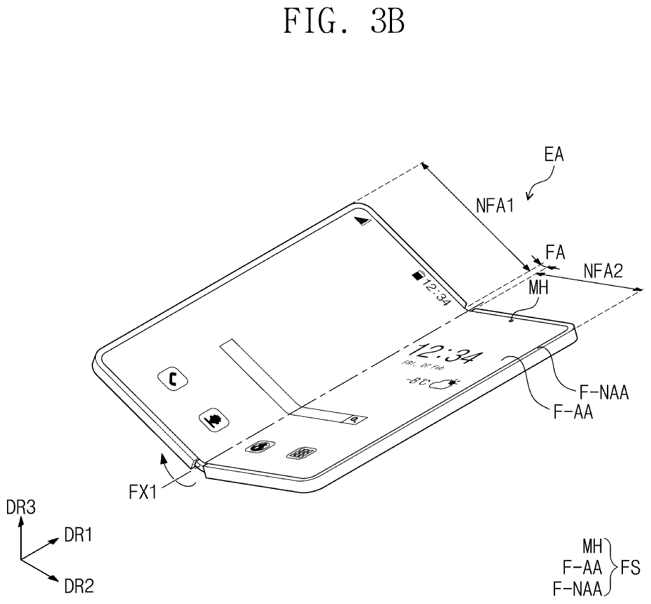

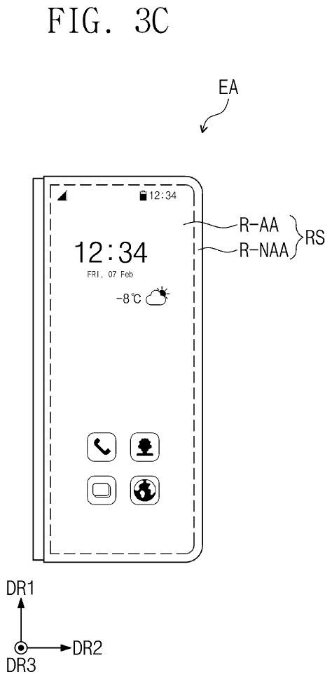

FIG. 3A is a perspective view of an unfolded state of an electronic apparatus EA according to an embodiment. The electronic apparatus EA of an embodiment may be an apparatus activated according to an electrical signal. For example, the electronic apparatus EA may be a smart phone, a tablet, a car navigation system, a game console, a portable electronic device, or a wearable device, but an embodiment of the inventive concept is not limited thereto. In FIG. 3A, or the like, the electronic apparatus EA is illustrated as a smartphone.

The electronic apparatus EA may include a first display surface FS defined by a first directional axis DR1 and a second directional axis DR2 intersecting the first directional axis DR1. The electronic apparatus EA may provide an image IM to a user through the first display surface FS. The electronic apparatus EA may display an image IM toward a third directional axis DR3 on the first display surface FS parallel to each of the first directional axis DR1 and the second directional axis DR2. The image IM may include a dynamic image and a static image.

In the present specification, the first directional axis DR1 and the second directional axis DR2 may be orthogonal to each other, and the third directional axis DR3 may be a normal direction to a plane defined by the first directional axis DR1 and the second directional axis DR2. The thickness direction of the electronic apparatus EA may be parallel to the third directional axis DR3. The thickness direction of the electronic apparatus EA may use the same drawing symbol as the third directional axis DR3. The front (or upper surface) and the back (or lower surface) are opposite each other in the third directional axis DR3, and the normal directions of each of the front (or upper surface) and the back (or lower surface) may be parallel to the third directional axis DR3. The front (or upper surface) means a surface adjacent to the first display surface FS, and the back (or lower surface) means a surface spaced from the first display surface FS. In addition, the back (or lower surface) means a surface close to the second display surface RS described below. The upper side means a direction approaching the first display surface FS, and the lower side means a direction away from the first display surface FS.

The cross-section means a plane parallel to the thickness direction DR3, and the plane means a plane perpendicular to the thickness direction DR3. The plane means a plane defined by the first directional axis DR1 and the second directional axis DR2.

The directions indicated by the first to third directional axes DR1, DR2, and DR3 described in this specification are relative concepts and may be converted into other directions. In addition, the directions indicated by the first to third directional axes DR1, DR2, and DR3 may be described as the first to third directions, and the same drawing symbols may be used.

The electronic apparatus EA may detect external input applied from the outside. The external input may include various types of inputs provided from the outside of the electronic apparatus EA. For example, the external input may include contact by a part of the body, such as a user's hand as well as external input (for example, hovering) applied close to the electronic apparatus EA or at a predetermined distance. In addition, the external input may have various forms such as force, pressure, temperature, and light.

The electronic apparatus EA may include a first display surface FS and a second display surface RS. The first display surface FS may include a first active area F-AA and a first peripheral area F-NAA. The first display surface FS may further include a sub-area MH. The second display surface RS may be defined as a surface facing at least a portion of the first display surface FS. That is, the second display surface RS may be defined as a portion of the rear surface of the electronic apparatus EA.

The first active area F-AA may be an area that is activated according to an electrical signal. The first active area F-AA may be an area where an image IM is displayed and may detect various forms of external input.

The first peripheral area F-NAA may be adjacent to the first active area F-AA. The light transmittance of the first peripheral area F-NAA may be lower than the light transmittance of the first active area F-AA. The first peripheral area F-NAA may have a predetermined color. The first peripheral area F-NAA may surround the first active area F-AA. Accordingly, the shape of the first active area F-AA may be substantially defined by the first peripheral area F-NAA. However, this is an illustration, and the first peripheral area F-NAA may be disposed adjacent to only one side of the first active area F-AA or may be omitted.

The sub-area MH may detect an external subject received through the display surfaces FS and RS or provide a sound signal such as a voice to the outside through the display surfaces FS and RS. An optical signal such as visible light or infrared light may move to the sub-area MH.

Various electronic modules may be disposed to correspond to the sub-area MH. For example, an electronic module may include at least one among a camera, a speaker, a light detection sensor, and a heat detection sensor. The electronic apparatus EA may include an electronic module that captures an external image through visible light passing through the sub-area MH or determines the accessibility of an external object through infrared light. The electronic module may include a plurality of components and is not limited to any one embodiment.

The sub-area MH may be disposed within the first active area F-AA. However, this is an illustration and is not limited to any one embodiment. For example, the sub-area MH may be surrounded by the first peripheral area F-NAA or may be surrounded by the first active area F-AA and the first peripheral area F-NAA. Although one sub-area MH is illustrated in FIG. 3A, or the like, the sub-areas MH may be provided in multiple numbers.

An electronic apparatus EA of an embodiment may include at least one folding area FA and a plurality of non-folding areas NFA1 and NFA2 extending from the folding area FA. For example, a first non-folding area NFA1, a folding area FA, and a second non-folding area NFA2 may be defined along a second direction DR2. The electronic apparatus EA of an embodiment may include a first non-folding area NFA1 and a second non-folding area NFA2 spaced apart from each other in the second direction DR2 with the folding area FA interposed therebetween. The first non-folding area NFA1 may be adjacent to one side of the folding area FA, and the second non-folding area NFA2 may be adjacent to the other side of the folding area FA. For example, the first non-folding area NFA1 may be disposed on one side of the folding area FA along the second direction DR2, and the second non-folding area NFA2 may be disposed on the other side of the folding area FA along the second direction DR2.

Although FIG. 3A or the like illustrate an embodiment of an electronic apparatus EA including one folding area FA, an embodiment of the inventive concept is not limited thereto, and a plurality of folding areas may be defined in the electronic apparatus EA. For example, the electronic apparatus according to an embodiment may include two or more folding areas and may also include three or more non-folding areas disposed with each of the folding areas interposed therebetween.

FIG. 3B is a perspective view showing a folding operation of the electronic apparatus EA according to an embodiment. FIG. 3C is a plan view of a folded state of the electronic apparatus EA according to an embodiment. FIG. 3D is a perspective view showing a folding operation of the electronic apparatus EA according to an embodiment.

Referring to FIG. 3B, the electronic apparatus EA according to an embodiment may be folded based on a first folding axis FX1 extending in a first direction DR1. In a folded state of the electronic apparatus EA, a folding area FA may have a predetermined curvature and a radius of curvature. The electronic apparatus EA may be folded based on the first folding axis FX1 so that a first non-folding area NFA1 and a second non-folding area NFA2 face each other and may be transformed into an in-folding state so that a first display surface FS is not exposed to the outside.

FIG. 3C may be a plan view showing the electronic apparatus EA in an in-folded state. Referring to FIG. 3C, in the electronic apparatus EA according to an embodiment, a second display surface RS may be visible to a user in an in-folded state. In this case, the second display surface RS may include a second active area R-AA that displays an image. The second active area R-AA may be an area activated according to an electrical signal. The second active area R-AA may be an area where an image is displayed, and various types of external inputs may be detected.

A second peripheral area R-NAA may be adjacent to the second active area R-AA. The light transmittance of the second peripheral area R-NAA may be lower than the light transmittance of the second active area R-AA. The second peripheral area R-NAA may have a predetermined color. The second peripheral area R-NAA may surround the second active area R-AA. Although not illustrated, the electronic apparatus EA may further include a sub-area in which an electronic module including various elements is disposed on the second display surface RS, and is not limited to any one embodiment.

Referring to FIG. 3D, the electronic apparatus EA according to an embodiment may be folded based on a second folding axis FX2 extended in a first direction DR1. The electronic apparatus EA may be folded based on the second folding axis FX2 and transformed into an out-folding state so that a first display surface FS is exposed to the outside. In an embodiment, the electronic apparatus EA may be configured such that the in-folding or out-folding operation is mutually repeated from the unfolding operation but is not limited thereto.

In FIGS. 3A to 3D, folding based on one folding axis FX1 or FX2 is illustrated as an embodiment, but the number of folding axes and the number of non-folding areas according to the folding axis in the electronic apparatus according to an embodiment are not limited thereto. For example, the electronic apparatus may be folded based on a plurality of folding axes so that a portion of each of the first display surface FS and the second display surface RS faces each other. In addition, the first and second folding axes FX1 and FX2 are illustrated as being parallel to the long side of the electronic apparatus EA, but an embodiment of the inventive concept is not limited thereto, and the first and second folding axes FX1 and FX2 may be parallel to the short side of the electronic apparatus EA.

In the electronic apparatus EA, the first non-folding area NFA1 and the second non-folding area NFA2 may be defined as portions having display surfaces FS and RS parallel to a plane defined by the first directional axis DR1 and the second directional axis DR2 in a folded state, as illustrated in FIG. 3C, and the folding area FA may be defined as an area between the first non-folding area NFA1 and the second non-folding area NFA2. The folding area FA may include a curved part that is bent to have a predetermined curvature in a folded state.

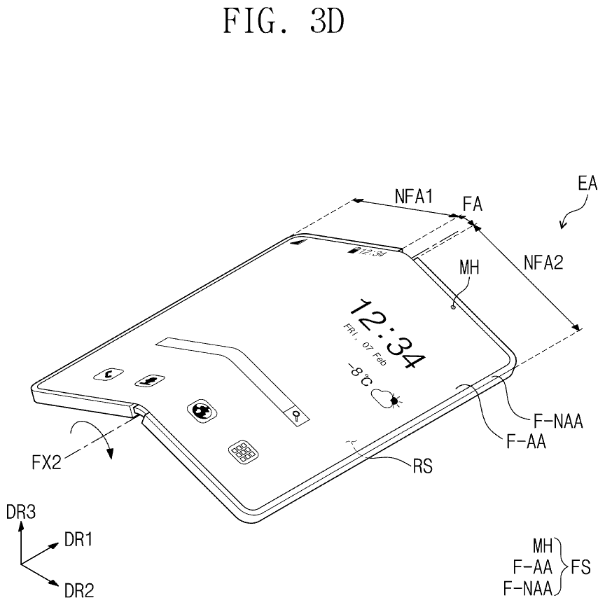

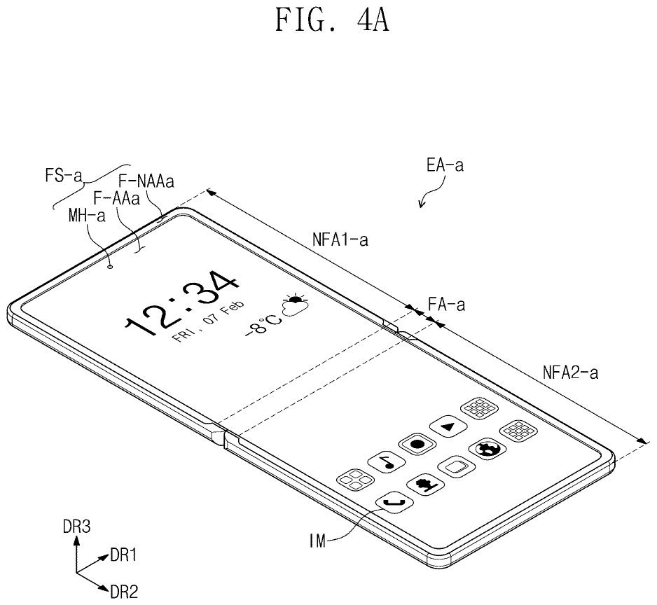

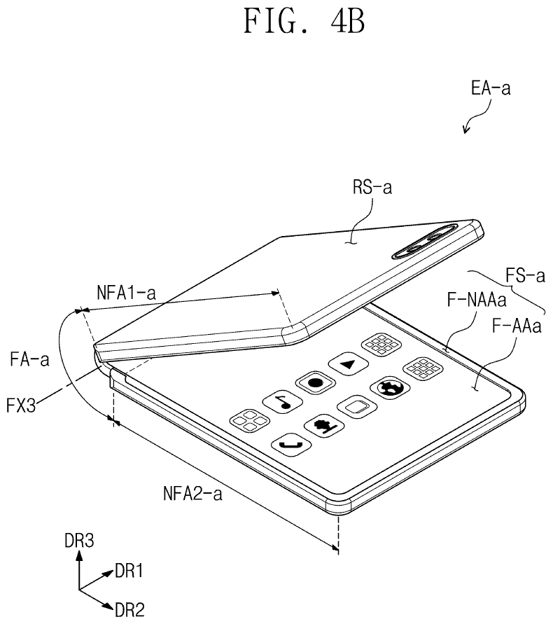

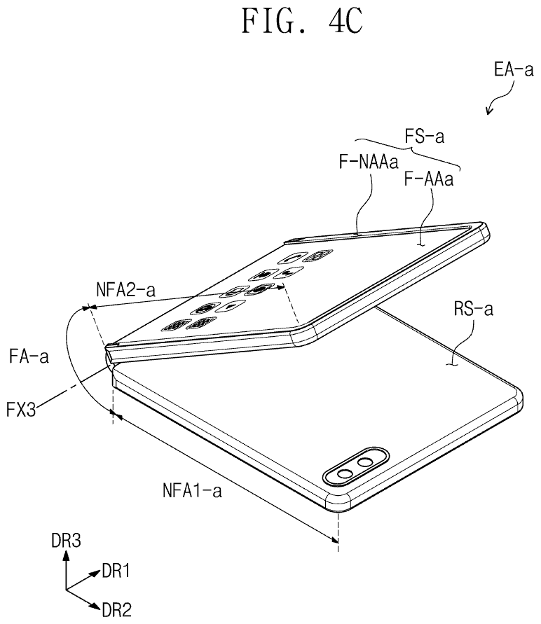

FIGS. 4A to 4C are perspective views showing an electronic apparatus EA-a according to another embodiment of the inventive concept. FIG. 4A is a perspective view showing an unfolded state of the electronic apparatus EA-a. FIGS. 4B and 4C are perspective views showing a folding operation of the electronic apparatus EA-a. FIG. 4B is a perspective view showing an in-folding operation of the electronic apparatus EA-a illustrated in FIG. 4A. FIG. 4C is a perspective view showing an out-folding operation of the electronic apparatus EA-a illustrated in FIG. 4A.

The electronic apparatus EA-a may be folded based on a third folding axis FX3 that is parallel to the first directional axis DR1. Referring to FIGS. 4B and 4C, the extension direction of the third folding axis FX3 may be parallel to the extension direction of the short side of the electronic apparatus EA-a.

The electronic apparatus EA-a may be divided into a folding area FA-a, a first non-folding area NFA1-a adjacent to one side of the folding area FA-a, and a second non-folding area NFA2-a adjacent to the other side of the folding area FA-a. The first non-folding area NFA1-a and the second non-folding area NFA2-a may be spaced apart from each other with the folding area FA-a therebetween.

The folding area FA-a may be an area folded based on the third folding axis FX3. When the electronic apparatus EA-a is folded, the folding area FA-a may have a predetermined curvature and a radius of curvature. The first non-folding area NFA1-a and the second non-folding area NFA2-a face each other, and the electronic apparatus EA-a may be in-folded so that the display surface FS-a is not exposed to the outside.

Referring to FIG. 4A, in an embodiment, the electronic apparatus EA-a may be recognized by the user in an open state (that is, an unfolded state). As described with reference to FIGS. 3A to 3D, the display surface FS-a of the electronic apparatus EA-a may include an active area F-AAa and a peripheral area F-NAAa. The display surface FS-a may further include a sub-area MH-a. The active area F-AAa may be an area where an image IM is displayed, and various forms of external input may be detected.

Referring to FIG. 4B, the electronic apparatus EA-a of an embodiment may be in an in-folded state, and the back surface RS-a may be visible to the user. For example, the back surface RS-a may function as a second display surface that displays an image or video. In addition, the back surface RS-a may also be provided with a sub-area in which an electronic module including various configurations are disposed.

Referring to FIG. 4C, the electronic apparatus EA-a may be folded based on the third folding axis FX3 and may be transformed into an out-folding state in which one area of the back surface RS-a overlapping the first non-folding area NFA1-a and the other area overlapping the second non-folding area NFA2-a face each other.

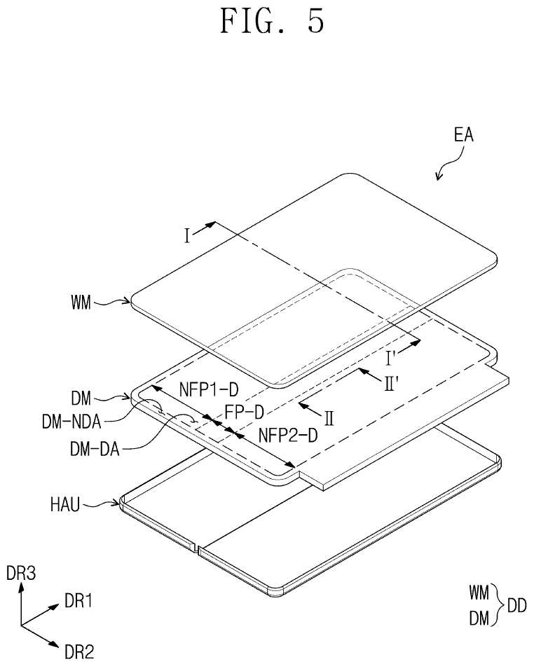

FIG. 5 is an exploded perspective view of the electronic apparatus EA illustrated in FIG. 3A. Hereinafter, the description of the electronic apparatus EA may be equally applied to the electronic apparatus EA-a illustrated in FIGS. 4A to 4C.

FIG. 5 is an exploded perspective view of the electronic apparatus EA of an embodiment. Referring to FIG. 5, the electronic apparatus EA may include a display device DD. In addition, the electronic apparatus EA may further include a housing HAU. The display device DD may include a display module DM and a window member WM disposed on the display module DM.

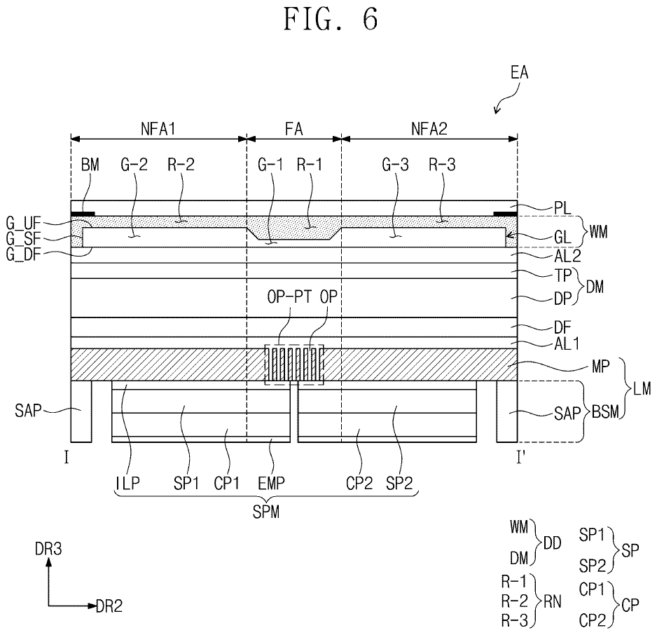

An image IM (FIG. 3A) generated in the display module DM may pass through the window member WM and be provided to a user. The window member WM may be folded based on at least one folding axis FX1 or FX2 (FIGS. 3B and 3D). The window member WM may include a glass substrate GL (FIG. 6) and a polymer layer RN (FIG. 6) described below. The window member WM including a polymer layer RN (FIG. 6) according to an embodiment may exhibit easy folding and unfolding repetition, improved impact resistance, and excellent reliability. Accordingly, the electronic apparatus EA of an embodiment including the window member WM may exhibit excellent reliability and excellent display quality.

The display module DM may display an image according to an electrical signal and send/receive information regarding an external input. A display area DM-DA and a non-display area DM-NDA may be defined in the display module DM.

The display area DM-DA may be defined as an area that emits an image provided by the display module DM. The display area DM-DA of the display module DM may correspond to at least a portion of the first active area F-AA (FIG. 3A).

A driving circuit or driving wiring for driving the display area DM-DA may be disposed in the non-display area DM-NDA. The non-display area DM-NDA may be adjacent to the display area DM-DA. For example, the non-display area DM-NDA may surround the display area DM-DA. However, this is an illustration, and the non-display area DM-NDA may be defined in various shapes and is not limited to any one embodiment.

The display module DM may be folded based on the folding axes FX1 and FX2 (FIGS. 3B and 3D). The display module DM may include a folding display part FP-D and non-folding display parts NFP1-D and NFP2-D. The folding display part FP-D may correspond to a folding area FA (FIG. 3A), and the non-folding display parts NFP1-D and NFP2-D may correspond to non-folding areas NFA1 and NFA2 (FIG. 3A). In this specification, the folding part of the display module DM is referred to as the folding display part FP-D, and the first and second non-folding parts of the display module DM are referred to as the first and second non-folding display parts NFP1-D and NFP2-D, respectively.

The folding display part FP-D may correspond to a portion that folds based on the folding axes FX1 and FX2 (FIGS. 3B and 3D). The non-folding display parts NFP1-D and NFP2-D may include a first non-folding display part NFP1-D and a second non-folding display part NFP2-D. The first non-folding display part NFP1-D and the second non-folding display part NFP2-D may be spaced apart from each other in the second direction DR2 with the folding display part FP-D therebetween. The first non-folding display part NFP1-D may be adjacent to one side of the folding display part FP-D, and the second non-folding display part NFP2-D may be adjacent to the other side of the folding display part FP-D. The first non-folding display part NFP1-D may be disposed at one side of the folding display part FP-D along the second direction DR2, and the second non-folding display part NFP2-D may be disposed at the other side of the folding display part FP-D along the second direction DR2. The first non-folding display part NFP1-D may be a portion corresponding to the first non-folding area NFA1 (FIG. 3A). The second non-folding display part NFP2-D may be a portion corresponding to the second non-folding area NFA2 (FIG. 3A).

The housing HAU may include a material having relatively high rigidity. For example, the housing HAU may include a plurality of frames and/or plates composed of glass, plastic, or metal. The housing HAU may provide a predetermined accommodation space. The display module DM may be accommodated within the accommodation space and protected from external impact.

FIG. 6 is a cross-sectional view showing a portion corresponding to line I-I′ shown in FIG. 5. FIG. 6 may be a cross-sectional view showing an electronic apparatus EA of an embodiment. In FIG. 6, the housing HAU (FIG. 5) is omitted for convenience of explanation.

Referring to FIG. 6, the electronic apparatus EA may further include a protective layer PL, an upper adhesive layer AL2, a lower module LM, a lower adhesive layer AL1, and a lower protective film DF. In addition, the electronic apparatus EA may further include a printing layer BM disposed on one surface of the protective layer PL. The protective layer PL may be disposed on a window member WM. The upper adhesive layer AL2 may be disposed between the display module DM and the window member WM. The lower module LM, the lower adhesive layer AL1, and the lower protective film DF may be disposed between the display device DD and the housing HAU (FIG. 5).

The lower module LM may be disposed under the display module DM. The lower module LM may include a support plate MP and a lower support member BSM. The lower module LM illustrated in FIG. 6 is an exemplary configuration, and the combination of the configurations included in the lower module LM in the electronic apparatus EA of an embodiment may vary depending on the size of the electronic apparatus EA, the shape of the electronic apparatus EA, or the operating characteristics of the electronic apparatus EA.

The support plate MP may include a metal material or a polymer material. For example, the support plate MP may be formed by including stainless steel, aluminum, or an alloy thereof. Alternatively, the support plate MP may be formed of a polymer material. A plurality of openings OP may be defined in the support plate MP. The support plate MP may include an opening pattern OP-PT in which a plurality of openings OP are defined. The opening pattern OP-PT may be formed in the folding area FA.

The lower support member BSM may include a support member SPM and a filling member SAP. On a plane, the support member SPM may be configured to overlap most of the area of the display module DM. The filling member SAP may be configured to be disposed on the outside of the support member SPM and overlap the outer surface of the display module DM.

The support member SPM may include at least one of a support layer SP, a cushion layer CP, a shield layer EMP, and an interlayer bonding layer ILP. The configuration of the support member SPM illustrated in FIG. 6 is an illustration, and an embodiment of the inventive concept is not limited thereto. For example, some of the support layer SP, the cushion layer CP, the shield layer EMP, and the interlayer bonding layer ILP may be omitted, or the stacking order thereof may be modified to a different order from that in FIG. 6, or additional configurations other than the illustrated configuration may be further included in the support member SPM.

The support layer SP may include a metal material or a polymer material. The support layer SP may be disposed under the support plate MP. For example, the support layer SP may be a thin film metal substrate. The support layer SP may include a first sub-support layer SP1 and a second sub-support layer SP2 spaced apart in the second direction DR2. The first sub-support layer SP1 and the second sub-support layer SP2 may be spaced apart in an area corresponding to the folding axes FX1 and FX2 (FIGS. 3B and 3D). The support layer SP may be provided as the first sub-support layer SP1 and the second sub-support layer SP2 spaced apart in the folding area FA and improve the folding characteristics of the electronic apparatus EA.

The cushion layer CP may be disposed under the support layer SP. The cushion layer CP may prevent the pressing phenomenon and plastic deformation of the support plate MP due to external impact and force. The cushion layer CP may improve the impact resistance of the electronic apparatus EA. The cushion layer CP may include an elastic polymer (elastomer) such as a sponge, a foam, or a urethane resin. In addition, the cushion layer CP may be formed by including at least one of an acrylic polymer, a urethane-containing polymer, a silicone-containing polymer, or an imide-containing polymer. However, this is an illustration, and an embodiment of the inventive concept is not limited thereto.

The cushion layer CP may include a first sub-cushion layer CP1 and a second sub-cushion layer CP2 spaced apart in the second direction DR2. The first sub-cushion layer CP1 and the second sub-cushion layer CP2 may be spaced apart from each other in a portion corresponding to the folding axes FX1 and FX2 (FIGS. 3B and 3D). The cushion layer CP may improve the folding characteristics of the electronic apparatus EA by being provided as the first sub-cushion layer CP1 and the second sub-cushion layer CP2 spaced apart from the folding area FA.

The shielding layer EMP may be an electromagnetic shielding layer or a heat dissipation layer. In addition, the shielding layer EMP may function as a bonding layer.

The interlayer bonding layer ILP may bond the configurations of the support plate MP and the support member SPM. The interlayer bonding layer ILP may be provided in the form of a bonding resin layer or an adhesive tape. In FIG. 6, the interlayer bonding layer ILP is illustrated as being provided as two configurations spaced apart in an area corresponding to the folding axes FX1 and FX2 (FIGS. 3B and 3D), but an embodiment of the inventive concept is not limited thereto. Unlike the illustration, the interlayer bonding layer ILP may be provided as a single layer that is not separated from the area corresponding to the folding axes FX1 and FX2 (FIGS. 3B and 3D).

The filling part SAP may be disposed on the outside of the support layer SP and the cushion layer CP. The filling part SAP may be disposed between the support plate MP and the housing HAU (FIG. 5). The filling part SAP may fill the space between the support plate MP and the housing HAU (FIG. 5) and may fix the support plate MP.

The lower protective film DF may be disposed between the display module DM and the support plate MP. The lower protective film DF may be disposed under the display module DM to protect the back surface of the display module DM. The lower protective film DF may entirely overlap the display module DM. The lower protective film DF may include a polymer material. For example, the lower protective film DF may be a polyimide film or a polyethylene terephthalate film. However, this is an illustration, and the lower protective film DF is not limited thereto.

The lower adhesive layer AL1 may be disposed between the support plate MP and the lower protective film DF. The support plate MP and the lower protective film DF may be combined through the lower adhesive layer AL1. The lower adhesive layer AL1 may include a pressure sensitive adhesive (PSA), an optically clear adhesive film (OCA), or an optically clear adhesive resin layer (OCR). However, this is an illustration, and an embodiment of the inventive concept is not limited thereto. Unlike the illustration, the lower adhesive layer AL1 may be omitted.

The display module DM may include a display panel DP and an input detection part TP disposed on the display panel DP. The display panel DP may be configured to substantially generate an image. According to an embodiment, the display panel DP may be folded based on folding axes FX1 and FX2 (FIGS. 3B and 3D).

The input detection part TP may detect an external input, change same into a predetermined input signal, and provide the input signal to the display panel DP. For example, the input detection part TP may be a touch detection part that detects a touch. The input detection part TP may recognize a direct touch of a user, an indirect touch of a user, a direct touch of an object, or an indirect touch of an object.

The input detection part TP may detect at least one among the position of a touch applied from the outside and the intensity (pressure) of the touch. In an embodiment, the input detection part TP may have various structures or be composed of various materials and is not limited to any one embodiment. For example, the input detection part TP may detect an external input in a capacitive manner. The display panel DP may receive an input signal from the input detection part TP and generate an image corresponding to the input signal.

An upper adhesive layer AL2 may be disposed on the input detection part TP. The upper adhesive layer AL2 may include a pressure sensitive adhesive (PSA), an optically clear adhesive film (OCA), or an optically clear adhesive resin layer (OCR). However, this is an illustration, and an embodiment of the inventive concept is not limited thereto. Unlike the illustration, the upper adhesive layer AL2 may be omitted.

The protective layer PL may be a functional layer that protects one surface (for example, upper surface) of the window member WM. For example, the protective layer PL may include polyethylene terephthalate (PET). The protective layer PL may include an anti-fingerprint coating agent, a hard coating agent, an antistatic agent, or the like. Unlike the illustration, the protective layer PL may be omitted.

The printing layer BM may be provided on the lower surface of the protective layer PL adjacent to the window member WM. The printing layer BM may be disposed in an edge area of the protective layer PL. The portion where the printing layer BM is provided may be a bezel area. The printing layer BM may overlap the first peripheral area F-NAA illustrated in FIG. 3A, or the like. The printing layer BM may be an ink-printed layer. In addition, the printing layer BM may be a layer formed by including a pigment or a dye. For example, the printing layer BM may be a layer formed by including a black pigment or a black dye.

In the present specification, when a component overlaps another component, it means overlapping on a plane. The case of overlapping is not limited to the case of the same area and the same shape and also includes the case of different areas and/or different shapes.

In an embodiment, the window member WM may include a glass substrate GL and a polymer layer RN. The glass substrate GL may include a lower surface G_DF, an upper surface G_UF, and a side surface G_SF. The lower surface G_DF and the upper surface G_UF may face each other in the thickness direction DR3, and the side surface G_SF may be disposed between the lower surface G_DF and the upper surface G_UF. The side surface G_SF of the glass substrate GL may be parallel to the thickness direction DR3. The lower surface G_DF, the upper surface G_UF, and the side surface G_SF may have an integral shape. The lower surface G_DF of the glass substrate GL may be adjacent to the display module DM and may be flat.

The glass substrate GL may be divided into first to third portions G-1, G-2 and G-3. The first portion G-1 of the glass substrate GL may be a portion overlapping the folding area FA. The second portion G-2 of the glass substrate GL may be a portion overlapping the first non-folding area NFA1. The third portion G-3 of the glass substrate GL may be a portion overlapping the second non-folding area NFA2. In the glass substrate GL, the thickness of the first portion G-1 may be smaller than the thickness of the second portion G-2 and the thickness of the third portion G-3. Except for a boundary where the first portion G-1 and the second portion G-2 contact each other, the thickness of the first portion G-1 may be smaller than the thickness of the second portion G-2. Except for a boundary where the first portion G-1 and the third portion G-3 contact each other, the thickness of the first portion G-1 may be smaller than the thickness of the third portion G-3. Since the first portion G-1 overlapping the folding area FA of the glass substrate GL has a smaller thickness than the second and third portions G-2 and G-3 overlapping the first and second non-folding areas NFA1 and NFA2, the folding operation of the glass substrate GL may be facilitated.

In the first portion G-1 of the glass substrate GL, the thickness of a central part may be smaller than the thickness of an edge part. In the second direction DR2, the central part may be a portion spaced apart from the second portion G-2 and the third portion G-3 with the edge part therebetween. The central part may be a portion having a uniform thickness. The thickness of the edge part may gradually decrease from the second portion G-2 and the third portion G-3 toward the central part. However, this is an illustration, and an embodiment of the inventive concept is not limited thereto.

The polymer layer RN may be disposed on at least one among the upper surface G_UF of the glass substrate GL and the lower surface G_DF of the glass substrate GL. Referring to FIG. 6, the polymer layer RN may be disposed on the upper surface G_UF of the glass substrate GL. Specifically, the polymer layer RN may be disposed to surround the upper surface G_UF of the glass substrate GL and the side surface G_SF of the glass substrate GL. For example, the polymer layer RN may be in contact with at least a portion of the glass substrate GL. The polymer layer RN may be in contact with the upper surface G_UF of the glass substrate GL and the side surface G_SF of the glass substrate GL.

The polymer layer RN may include an upper surface spaced apart from the glass substrate GL and a lower surface facing the upper surface in the thickness direction DR3. The upper surface of the polymer layer RN may be a flat surface. The lower surface of the polymer layer RN may be in contact with the upper surface G_UF of the glass substrate GL and may be an uneven surface.

The polymer layer RN may be divided into fourth to sixth portions R-1, R-2 and R-3. The fourth portion R-1 of the polymer layer RN may be a portion overlapping the folding area FA. The fifth portion R-2 of the polymer layer RN may be a portion overlapping the first non-folding area NFA1. The sixth portion R-3 of the polymer layer RN may be a portion overlapping the second non-folding area NFA2. The fourth to sixth portions R-1, R-2 and R-3 of the polymer layer RN may overlap the first to third portions G-1, G-2 and G-3 of the glass substrate GL, respectively.

In the polymer layer RN, the thickness of the fourth portion R-1 may be greater than the thickness of the fifth portion R-2 and the thickness of the sixth portion R-3. Except for the boundary where the fourth portion R-1 and the fifth portion R-2 contact each other, the thickness of the fourth portion R-1 may be greater than the thickness of the fifth portion R-2. Except for the boundary where the fourth portion R-1 and the sixth portion R-3 contact each other, the thickness of the fourth portion R-1 may be greater than the thickness of the sixth portion R-3.

In the fourth portion R-1 of the polymer layer RN, the thickness of the central part may be greater than the thickness of the edge part. In the second direction DR2, the central part may be a portion spaced apart from the fifth portion R-2 and the sixth portion R-3 with the edge part therebetween. The central part may be a portion having a uniform thickness. The thickness of the edge part may gradually increase from the fifth portion R-2 and the sixth portion R-3 toward the center part. However, this is an illustration, and an embodiment of the inventive concept is not limited thereto.

The fourth portion R-1 of the polymer layer RN overlapping the first portion G-1 having a relatively small thickness on the glass substrate GL may have a relatively large thickness. The sum of the thickness of the first portion G-1 and the fourth portion R-1 may be substantially the same as the sum of the thickness of the second portion G-2 and the thickness of the fifth portion R-2. The sum of the thickness of the first portion G-1 and the thickness of the fourth portion R-1 may be substantially the same as the sum of the thickness of the third portion G-3 and the thickness of the sixth portion R-3. In this case, the thickness of the window member WM may be uniform. In this specification, substantially the same includes cases where the physical values are the same and cases where there is a difference within the range of process errors that may generally occur.

The polymer layer RN may have a hardness of about 1.0 MPa or more and about 10.0 MPa or less, and an elastic modulus of about 10 MPa or more and about 300 MPa or less. The polymer layer RN may have an indentation depth of about 1.0 μm or more and about 5.0 μm or less, and a creep value of about 2.0% or more and about 150.0% or less. In this case, the hardness, elastic modulus, indentation depth, and creep value of the polymer layer mean those measured by a Nano Indentation Tester (NID) at temperatures of about −5° C. and about 25° C.

A polymer layer having a hardness of less than about 1.0 MPa is weak to external impact, and a polymer layer having a hardness of more than about 10.0 MPa is not easy in repeating folding and unfolding. A polymer layer having an elastic modulus of less than about 10 MPa or more than 300 MPa is not easy in repeating folding and unfolding. A polymer layer having an indentation depth of less than about 1.0 μm is not easy in repeating folding and unfolding, and a polymer layer having an indentation depth of more than about 5.0 μm is weak to external impact. A polymer layer having a creep value of less than about 2.0% is not easy in repeating folding and unfolding, and a polymer layer having a creep value of more than about 150.0% is weak to external impact. In contrast, a polymer layer RN of an embodiment, which satisfies the hardness, the elastic modulus, the indentation depth, and the creep value of above-mentioned ranges may exhibit excellent folding reliability, excellent high-temperature and high-humidity reliability, and excellent impact resistance without an increase in thickness. The high-temperature and high-humidity reliability means that excellent reliability in high-temperature and high-humidity environment is exhibited, and the high-temperature and high-humidity environment means an environment with a temperature of about 85° C. and a humidity of about 85%. In addition, the polymer layer RN of an embodiment, in which the hardness, elastic modulus, indentation depth, and creep value satisfy the above-mentioned ranges, may improve the folding reliability and impact resistance of the electronic apparatus EA without increasing the thickness of the electronic apparatus EA.

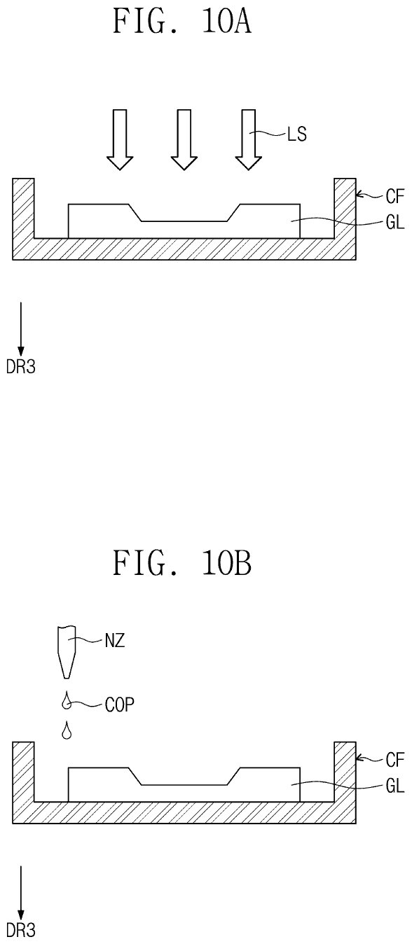

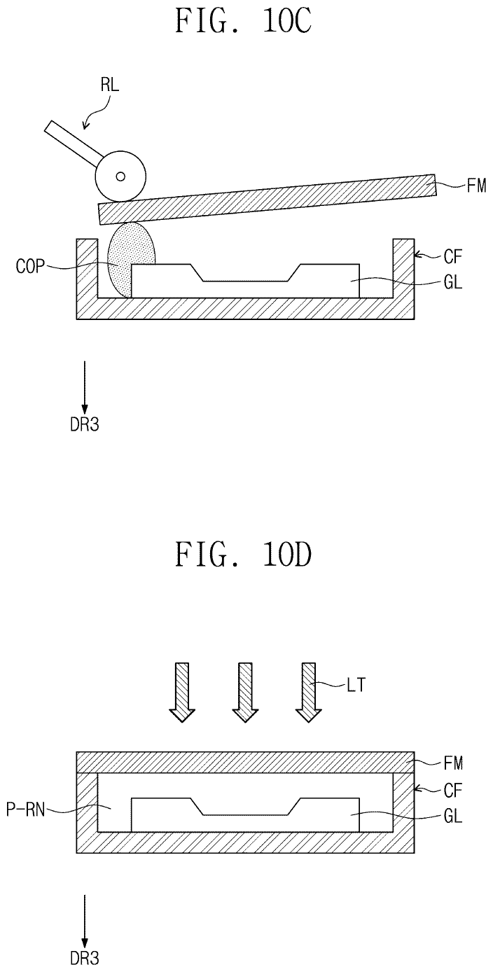

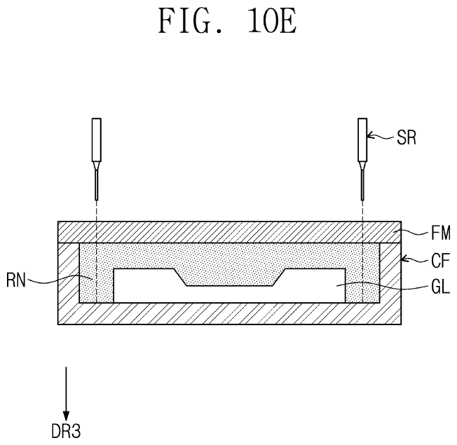

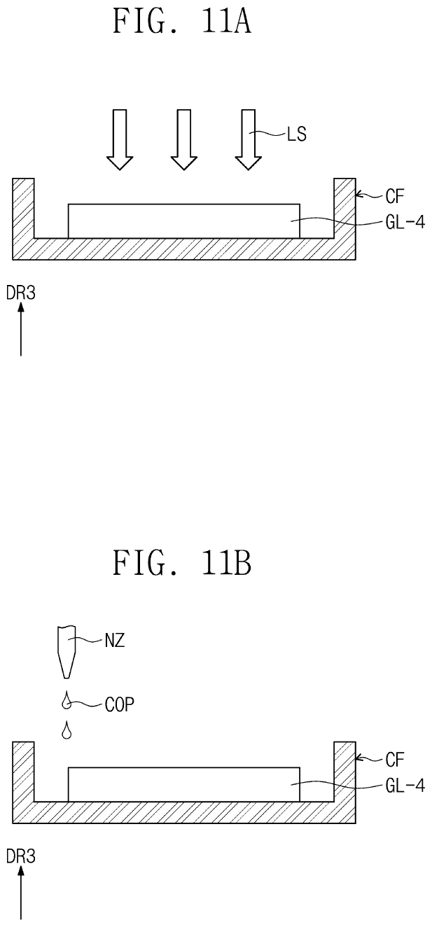

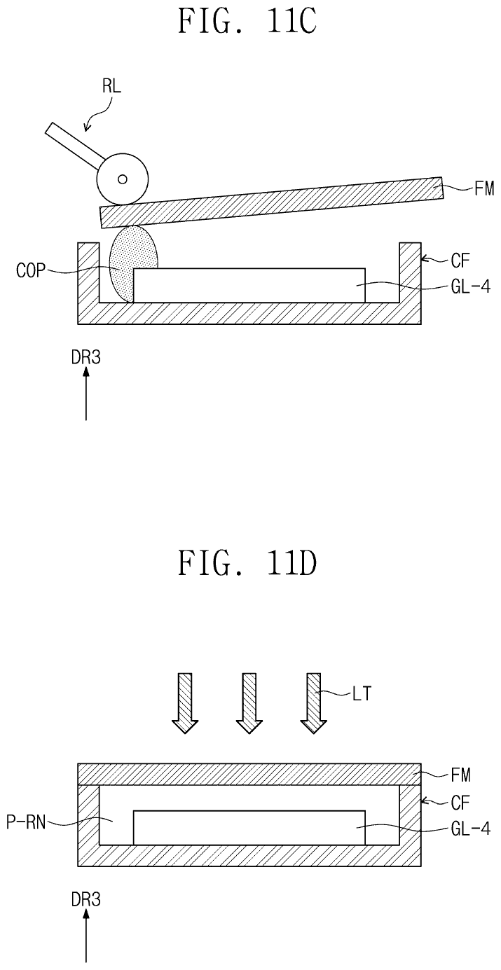

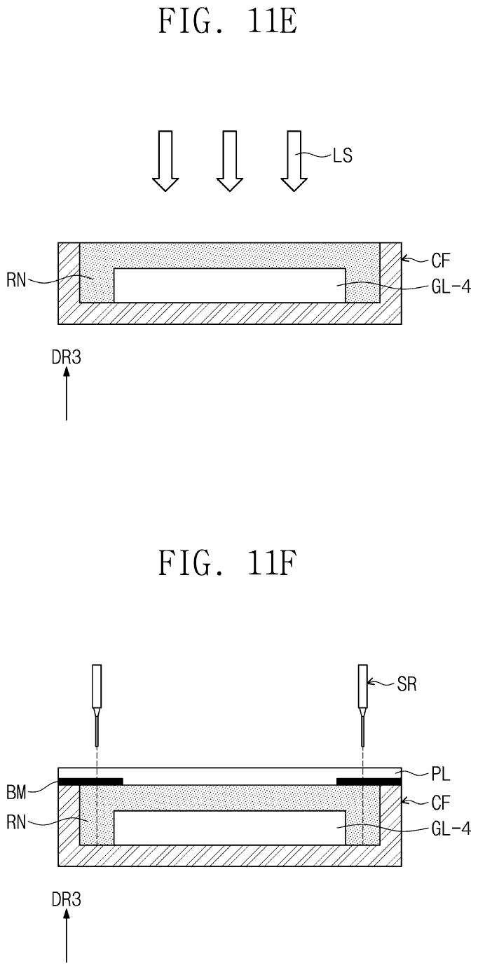

In an embodiment, the polymer layer RN may include a polymer derived from a resin composition COP (FIGS. 10B and 11B). The resin composition COP (FIGS. 10B and 11B) may include a polyurethane-forming composition, i.e., a polyisocyanate and a polyol, an acrylate containing a cycloalkyl group, and a photoinitiator. The polymer layer RN may be formed by photocuring the resin composition COP (FIGS. 10B and 11B). When the resin composition COP (FIGS. 10B and 11B) is photocured, a polymerization reaction occurs, and a polymer layer RN may be formed through the polymerization reaction. The polymer layer RN formed from the resin composition COP (FIGS. 10B and 11B) may satisfy the above-described hardness, elastic modulus, indentation depth, and creep value ranges. The polymer layer RN formed from the resin composition COP (FIGS. 10B and 11B) according to an embodiment and the window member WM including the same may exhibit excellent impact resistance and excellent folding reliability. The resin composition COP (FIGS. 10B and 11B) will be described in more detail below.

The difference in the refractive index of the glass substrate GL and the refractive index of the polymer layer RN may be about 0.3 or less. The refractive index of the polymer layer RN may be less than the refractive index of the glass substrate GL by about 0.3 or less. Alternatively, the refractive index of the polymer layer RN may be greater than the refractive index of the glass substrate GL by about 0.3 or more. For example, the refractive index of the polymer layer RN may be about 1.2 or more and about 1.8 or less, about 1.3 or more and about 1.7 or less, or about 1.4 or more and about 1.6 or less. The refractive index of the glass substrate GL may be about 1.5. In the present specification, the refractive index means the refractive index for light in the visible light wavelength range (for example, the wavelength range of about 380 nanometers (nm) or more and about 760 nm or less).

The polymer layer RN having a refractive index difference of 0.3 or less from the refractive index of the glass substrate GL may exhibit optical properties similar to those of the glass substrate GL. The polymer layer RN having the refractive index difference of 0.3 or less from the refractive index of the glass substrate GL may exhibit excellent display quality. The image IM (FIG. 3A) generated in the display module DM may be provided to the user by transmitting through the glass substrate GL and the polymer layer RN. When the difference in the refractive index of the glass substrate GL and the polymer layer RN is about 0.3 or less, the image IM (FIG. 3A) generated by the display module DM may be provided to the user without deterioration of the display quality. In contrast, when the difference in the refractive index of the glass substrate and the polymer layer is more than about 0.3, a difference in display quality occurs between the image transmitted through the glass substrate and the image transmitted through the polymer layer, resulting in deterioration of the display quality of the image.

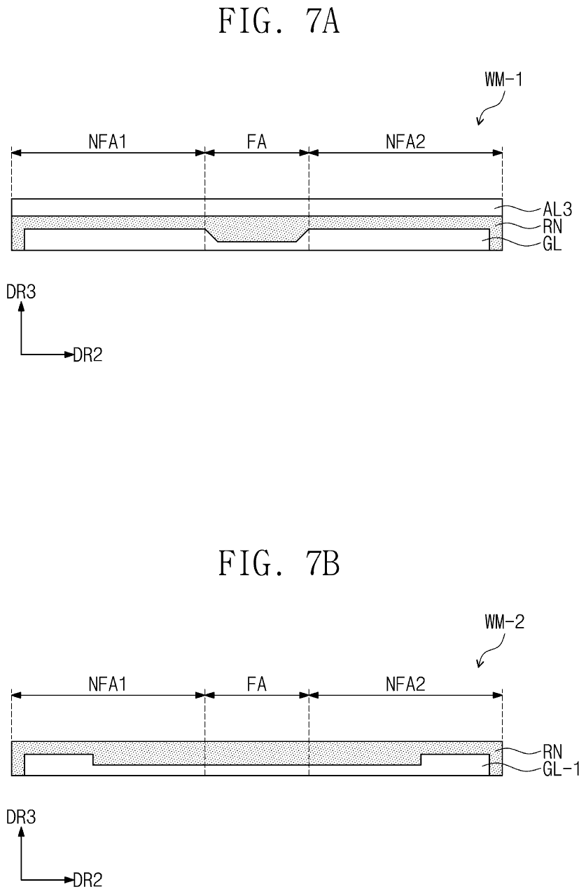

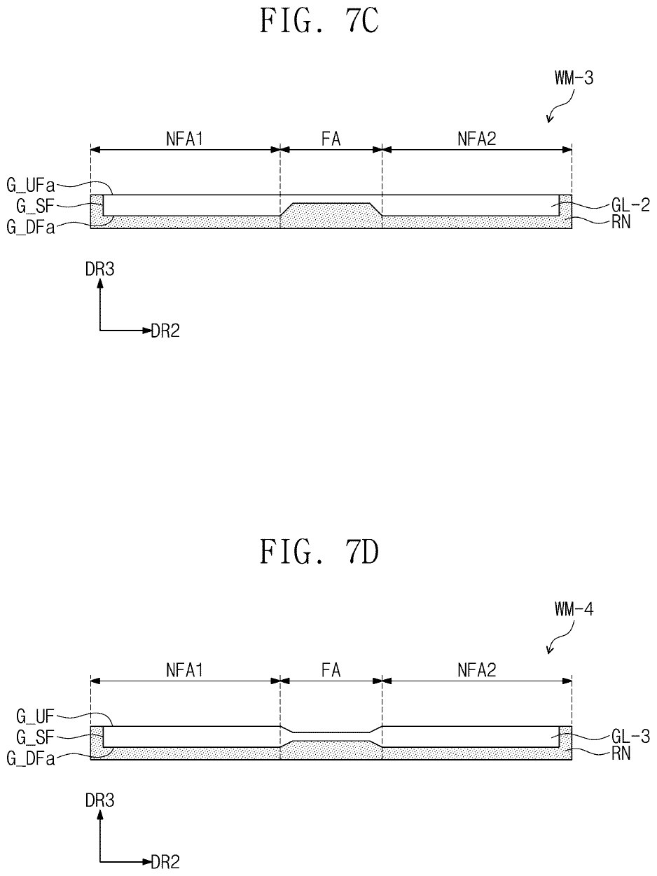

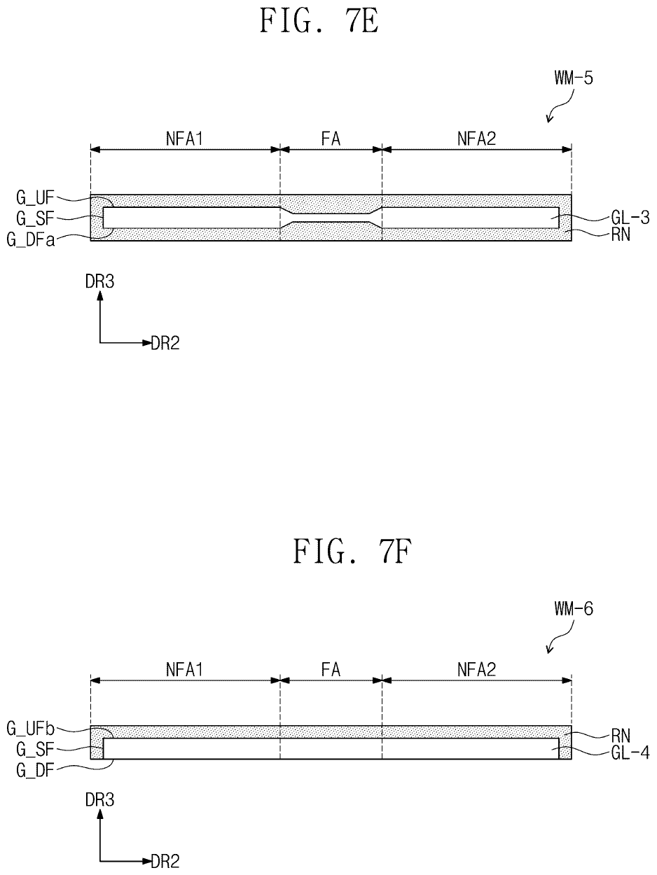

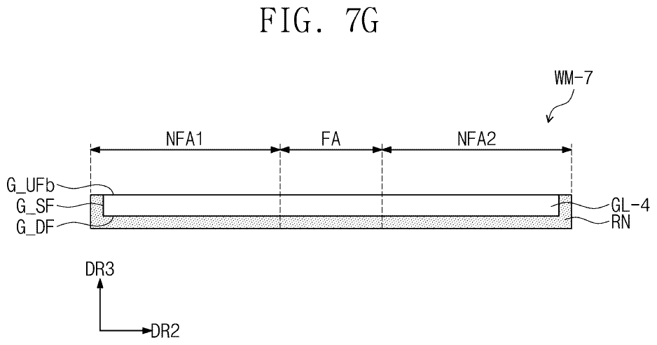

FIGS. 7A to 7G are cross-sectional views showing a window member according to another embodiment of the inventive concept. In the description of FIGS. 7A to 7G below, any content that overlaps with the content described with reference to FIGS. 1 to 6 will not be described again, and differences will be mainly described.

Compared to the window member WM illustrated in FIG. 6, the window member WM-1 illustrated in FIG. 7A differs in further including an adhesive layer AL3. The adhesive layer AL3 may be directly disposed on one surface (that is, the upper surface) of the polymer layer RN spaced apart from the glass substrate GL. The adhesive layer AL3 may be disposed between the polymer layer RN and the protective layer PL (FIG. 6). For example, the adhesive layer AL3 may include a pressure sensitive adhesive (PSA).

The window member WM-1 including the adhesive layer AL3 directly disposed on one surface of the polymer layer RN may exhibit characteristics in which folding and unfolding repetitions are easy without peeling at the interface between the window member WM and an adjacent component (for example, a protective layer PL). In the present specification, when a component is directly disposed/provided/formed on another component, it means that a third component is not disposed/provided/formed between the component and the other component. In other words, when a component is directly disposed/provided/formed on another component, it means that the component and the other component come into contact.

Compared to the window member WM illustrated in FIG. 6, the window member WM-2 illustrated in FIG. 7B has a difference in the shape of the glass substrate GL-1. The glass substrate GL-1 illustrated in FIG. 7B may have a shape similar to that of the glass substrate GL illustrated in FIG. 6, in which the width of the first portion G-1 is expanded, and the widths of the second and third portions G-2 and G-3 are reduced. In this case, the width means the width in the second direction DR2 perpendicular to the thickness direction DR3.

Referring to FIG. 7B, in each of the first and second non-folding areas NFA1 and NFA2, a portion of the glass substrate GL-1 may have a relatively small thickness, and the other portion of the glass substrate GL-1 may have a relatively large thickness. In the second direction DR2 perpendicular to the thickness direction DR3, the other portion of the glass substrate GL-1 may be spaced apart from the folding area FA with a portion of the glass substrate GL-1 interposed therebetween. A portion of the glass substrate GL-1 overlapping the first and second non-folding areas NFA1 and NFA2 may have the same thickness as another portion of the glass substrate GL-1 overlapping the folding area FA.

Compared to the window member WM illustrated in FIG. 6, the window member WM-3 illustrated in FIG. 7C has a difference in the shape of the glass substrate GL-2 and the disposition of the polymer layer RN. Referring to FIG. 7C, the glass substrate GL-2 may have a non-flat lower surface G_DFa and a flat upper surface G_UFa. The glass substrate GL-3 illustrated in FIG. 7C may have a shape in which the glass substrate GL illustrated in FIG. 6 is converted upside down. The polymer layer RN may be disposed under the lower surface G_DFa of the glass substrate GL-2. The polymer layer RN may be disposed to surround the lower surface G_DFa and the side surface G_SF of the glass substrate GL-2. The polymer layer RN may be disposed between the display module DM (FIG. 6) and the glass substrate GL-2.

Compared to the window member WM illustrated in FIG. 6, the window member WM-4 illustrated in FIG. 7D has a difference in the shape of the glass substrate GL-3 and the disposition of the polymer layer RN. Referring to FIG. 7D, the glass substrate GL-3 may have a non-flat lower surface G_DFa and an upper surface G_UF. In the glass substrate GL-3, the lower surface G_DFa and the upper surface G_UF may be vertically symmetrical. In the lower surface G_DFa of the glass substrate GL-3, a portion disposed in the folding area FA may be disposed lower than a portion disposed in the first and second non-folding areas NFA1 and NFA2. On the lower surface G_DFa of the glass substrate GL-3, a portion disposed in the folding area FA may be disposed on a different plane from portions disposed in the first and second non-folding areas NFA1 and NFA2. On the lower surface G_DFa of the glass substrate GL-3, a portion disposed in the folding area FA may be closer to the display module DM (FIG. 6) than portions disposed in the first and second non-folding areas NFA1 and NFA2. The polymer layer RN may be disposed under the lower surface G_DFa of the glass substrate GL-3. The polymer layer RN may be disposed to surround the lower surface G_DFa and the side surface G_SF of the glass substrate GL-3. The polymer layer RN may be disposed between the display module DM (FIG. 6) and the glass substrate GL-3.

Compared to the window member WM illustrated in FIG. 6, the window member WM-5 illustrated in FIG. 7E differs in the shape of the glass substrate GL-3 and the disposition of the polymer layer RN. The glass substrate GL-3 illustrated in FIG. 7E has the same shape as the glass substrate GL-3 illustrated in FIG. 7D, and the contents described with reference to FIG. 7D may be applied equally. Referring to FIG. 7E, the polymer layer RN may be disposed to surround the lower surface G_DFa, the upper surface G_UF, and the side surface G_SF of the glass substrate GL-3. The glass substrate GL-3 may be spaced apart from the display module DM (FIG. 6) with the polymer layer RN interposed therebetween. The glass substrate GL-3 may be spaced apart from the protective layer PL (FIG. 6) with the polymer layer RN interposed therebetween.

Compared to the window member WM illustrated in FIG. 6, the window member WM-6 illustrated in FIG. 7F has a difference in the shape of the glass substrate GL-4. Referring to FIG. 7F, the glass substrate GL-4 may have a flat lower surface G_DF and an upper surface G_UFb. The thickness of the glass substrate GL-4 may be uniform. The thickness of the glass substrate GL-4 in each of the folding area FA and the non-folding areas NFA1 and NFA2 may be substantially the same. The polymer layer RN may be disposed to surround the upper surface G_UFb and the side surface G_SF of the glass substrate GL-3.

Compared to the window member WM illustrated in FIG. 6, the window member WM-7 illustrated in FIG. 7G has a difference in the shape of the glass substrate GL-4 and the disposition of the polymer layer RN. The glass substrate GL-4 illustrated in FIG. 7G has the same shape as the glass substrate GL-4 illustrated in FIG. 7F, and the same description with reference to FIG. 7F may be applied thereto. Referring to FIG. 7G, the polymer layer RN may be disposed under the lower surface G_DF of the glass substrate GL-4. The polymer layer RN may be disposed to surround the lower surface G_DF and the side surface G_SF of the glass substrate GL-4. The polymer layer RN may be disposed between the display module DM (FIG. 6) and the glass substrate GL-4.

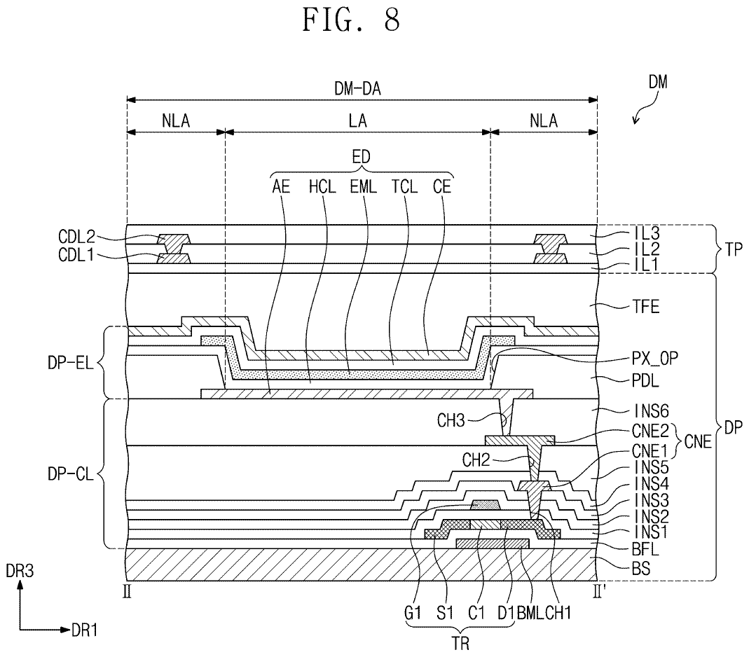

FIG. 8 is a cross-sectional view showing a portion corresponding to line II-II′ in FIG. 5. FIG. 8 may be a cross-sectional view showing an display area DM-DA of a display module DM according to an embodiment. The configuration of the display module DM illustrated in FIG. 8 is an illustration, and an embodiment of the inventive concept is not limited thereto.

The display panel DP of the display module DM may include a base substrate BS, a circuit layer DP-CL the disposed on the base substrate BS, and a display element layer DP-EL disposed on the circuit layer DP-CL. The base substrate BS may include a single layer or multiple layers. For example, the base substrate BS may include a first synthetic resin layer, an inorganic layer of a multilayer or single layer, and a second synthetic resin layer disposed on the inorganic layer of a multilayer or single layer. Each of the first synthetic resin layer and the second synthetic resin layer may include a polyimide-containing resin. In addition, each of the first synthetic resin layer and the second synthetic resin layer may include at least one among an acrylic resin, a methacryl resin, a polyisoprene-containing resin, a vinyl resin, an epoxy-containing resin, a urethane-containing resin, a cellulose-containing resin, a siloxane-containing resin, a polyamide-containing resin, and a perylene-containing resin. In the present specification, the containing resin means a resin that includes a functional group of “~~.”

In the display panel DP, the circuit layer DP-CL may include a transistor TR and the display element layer DP-EL may include a light emitting element ED. The transistor TR and the light emitting element ED may be disposed on the base substrate BS. Although one transistor TR is illustrated in FIG. 8, the display panel DP may actually include a plurality of transistors and at least one capacitor for driving the light emitting element ED.

The circuit layer DP-CL may be disposed on the base substrate BS. The circuit layer DP-CL may include a shielding electrode BML, a transistor TR, a connection electrode CNE, and a plurality of insulating layers BFL and INS1 to INS6. The plurality of insulating layers BFL and INS1 to INS6 may include a buffer layer BFL and first to sixth insulating layers INS1 to INS6. However, the laminated structure of the circuit layer DP-CL illustrated in FIG. 8 is an illustration, and the laminated structure of the circuit layer DP-CL may be changed depending on the configuration of the display panel DP and the process of the circuit layer DP-CL, or the like.

The shielding electrode BML may be disposed on the base substrate BS. The shielding electrode BML may overlap the transistor TR. The shielding electrode BML may block light incident on the transistor TR from the lower portion of the display panel DP to protect the transistor TR. The shielding electrode BML may include a conductive material. When a voltage is applied to the shielding electrode BML, the threshold voltage of the transistor TR disposed on the shielding electrode BML may be maintained. However, an embodiment of the inventive concept is not limited thereto, and the shielding electrode BML may be a floating electrode. The shielding electrode BML may be omitted.

The buffer layer BFL may be disposed on the base substrate BS to cover the shielding electrode BML. The buffer layer BFL may include an inorganic layer. The buffer layer BFL may improve the bonding strength between the semiconductor pattern or conductive pattern disposed on the buffer layer BFL and the base substrate BS.

The transistor TR may include a source S1, a channel C1, a drain D1, and a gate G1. The source S1, the channel C1, and the drain D1 of the transistor TR may be formed from a semiconductor pattern. The semiconductor pattern of the transistor TR may include polysilicone, amorphous silicon, or metal oxide, and any material having semiconductor properties may be applied without limitation to any.

The semiconductor pattern may include a plurality of regions that are distinguished by the size of the conductivity. Regions of the semiconductor pattern doped with a dopant or reduced with a metal oxide may have high conductivity and may actually serve as source and drain electrodes of the transistor TR. Regions of the semiconductor pattern with high conductivity may correspond to the source S1 and drain D1 of the transistor TR. Regions of the semiconductor pattern that are undoped or doped at a low concentration or have low conductivity due to non-reduced metal oxide may correspond to the channel C1 (or active) of the transistor TR.

The first insulating layer INS1 covers the semiconductor pattern of the transistor TR and may be disposed on the buffer layer BFL. The gate G1 of the transistor TR may be disposed on the first insulating layer INS1. On the plane, the gate G1 may overlap the channel C1 of the transistor TR. The gate G1 may function as a mask in the process of doping the semiconductor pattern of the transistor TR.

The second insulating layer INS2 covers the gate G1 and may be disposed on the first insulating layer INS1. The third insulating layer INS3 may be disposed on the second insulating layer INS2.

The connection electrode CNE may include a first connection electrode CNE1 and a second connection electrode CNE2 for electrically connecting the transistor TR and the light emitting element ED. However, the configuration of the connection electrode CNE for electrically connecting the transistor TR and the light emitting element ED is not limited thereto, and one of the first and second connection electrodes CNE1 and CNE2 may be omitted, or an additional connection electrode may be further included.

The first connection electrode CNE1 may be disposed on the third insulating layer INS3. The first connection electrode CNE1 may be connected to the drain D1 through a first contact hole CH1 penetrating the first to third insulating layers INS1 to INS3. The fourth insulating layer INS4 may cover the first connection electrode CNE1 and may be disposed on the third insulating layer INS3. The fifth insulating layer INS5 may be disposed on the fourth insulating layer INS4.

The second connection electrode CNE2 may be disposed on the fifth insulating layer INS5. The second connection electrode CNE2 may be connected to the first connection electrode CNE1 through a second contact hole CH2 penetrating the fourth and fifth insulating layers INS4 and INS5. The sixth insulating layer INS6 may cover the second connection electrode CNE2 and may be disposed on the fifth insulating layer INS5.

Each of the first to sixth insulating layers INS1 to INS6 may include an inorganic layer or an organic layer. For example, the inorganic layer may include at least one of aluminum oxide, titanium oxide, silicon oxide, silicon oxynitride, zirconium oxide, or hafnium oxide. The organic layer may include at least one of an acrylic resin, a methacrylic resin, a polyisoprene-containing resin, a vinyl resin, an epoxy-containing resin, a urethane-containing resin, a cellulose-containing resin, a siloxane-containing resin, a polyamide-containing resin, or a perylene-containing resin.

The display element layer DP-EL may include a pixel defining film PDL and a light emitting element ED. The light emitting element ED may include a first electrode AE, a hole control layer HCL, an emission layer EML, an electron control layer TCL, and a second electrode CE. The second electrode CE may be disposed on the first electrode AE. The emission layer EML may be disposed between the first electrode AE and the second electrode CE. The hole control layer HCL may be disposed between the first electrode AE and the emission layer EML. The electron control layer TCL may be disposed between the emission layer EML and the second electrode CE.

The first electrode AE may be disposed on the sixth insulating layer INS6. The first electrode AE may be connected to the second connection electrode CNE2 through a third contact hole CH3 penetrating the sixth insulating layer INS6. The first electrode AE may be electrically connected to the drain D1 of the transistor TR through the first and second connection electrodes CNE1 and CNE2.

The first electrode AE may be formed using a metal material, a metal alloy, or a conductive compound. The first electrode AE may be an anode or a cathode. However, an embodiment of the inventive concept is not limited thereto. In addition, the first electrode AE may be a pixel electrode. The first electrode AE may be a transmissive electrode, a transflective electrode, or a reflective electrode. The first electrode AE may include at least one selected from Ag, Mg, Cu, Al, Pt, Pd, Au, Ni, Nd, Ir, Cr, Li, Ca, LiF, Mo, Ti, W, In, Sn, and Zn, a compound of two or more selected therefrom, a mixture of two or more selected therefrom, or an oxide thereof.

When the first electrode AE is a transmissive electrode, the first electrode AE may include a transparent metal oxide, for example, indium tin oxide (ITO), indium zinc oxide (IZO), zinc oxide (ZnO), indium tin zinc oxide (ITZO), or the like. When the first electrode AE is a transflective electrode or a reflective electrode, the first electrode AE may include Ag, Mg, Cu, Al, Pt, Pd, Au, Ni, Nd, Ir, Cr, Li, Ca, LiF/Ca (a laminated structure of LiF and Ca), LiF/Al (a laminated structure of LiF and Al), Mo, Ti, W, or a compound or mixture thereof (for example, a mixture of Ag and Mg). Alternatively, the first electrode AE may have a multilayer structure including a reflective film or a transflective film formed using the above materials and a transparent conductive film formed using indium tin oxide (ITO), indium zinc oxide (IZO), zinc oxide (ZnO), indium tin zinc oxide (ITZO), or the like. For example, the first electrode AE may have a three-layer structure of ITO/Ag/ITO, but is not limited thereto. In addition, an embodiment of the inventive concept is not limited thereto, and the first electrode AE may include the metal material, a combination of two or more metal materials selected from the metal materials, or an oxide of the metal materials.

The pixel defining film PDL may be disposed on the sixth insulating layer INS6. The pixel defining film PDL may define a light emitting opening PX_OP that exposes a portion of the first electrode AE. A portion of the first electrode AE exposed by the light emitting opening PX_OP may be defined as a light emitting area LA.

The display area DM-DA of the display module DM may include a light emitting area LA and a light shielding area NLA. The area where the pixel defining film PDL is disposed may correspond to the light shielding area NLA. The light shielding area NLA may surround the light emitting area LA within the display area DM-DA.

The hole control layer HCL may be disposed on the first electrode AE and the pixel defining film PDL. The hole control layer HCL may be provided as a common layer overlapping the light emitting area LA and the light shielding area NLA. Unlike the illustration, the hole control layer HCL may be disposed within an area corresponding to the light emitting opening PX_OP. The hole control layer HCL may include at least one of a hole transport layer, a hole injection layer, or an electron blocking layer. The hole control layer HCL may include a known hole injection material and/or a known hole transport material.

The emission layer EML may be disposed on the hole control layer HCL. The emission layer EML may be disposed in an area corresponding to the light emitting opening PX_OP. Differently, the emission layer EML may be provided as a common layer. The emission layer EML may include an organic light emitting material and/or an inorganic light emitting material. The emission layer EML may emit any one color light among red, green, and blue. For example, the emission layer EML may emit blue light.

The electron control layer TCL may be disposed on the emission layer EML. The electron control layer TCL may be provided as a common layer overlapping the light emitting area LA and the light shielding area NLA. Unlike what is illustrated, the electron control layer TCL may also be disposed within an area corresponding to the light emitting opening PX_OP. The electron control layer TCL may include at least one of an electron transport layer, an electron injection layer, or a hole blocking layer. The electron control layer TCL may include a known electron injection material and/or a known electron transport material.

The second electrode CE may be disposed on the electron control layer TCL. The second electrode CE may be provided as a common layer overlapping the light emitting area LA and the light shielding area NLA. The second electrode CE may be a common electrode. The second electrode CE may be a cathode or an anode, but an embodiment of the inventive concept is not limited thereto. For example, if the first electrode AE is an anode, the second electrode CE may be a cathode, and if the first electrode AE is a cathode, the second electrode CE may be an anode.

The second electrode CE may be a transmissive electrode, a transflective electrode, or a reflective electrode. If the second electrode CE is a transmissive electrode, the second electrode CE may be formed using of a transparent metal oxide, for example, indium tin oxide (ITO), indium zinc oxide (IZO), zinc oxide (ZnO), indium tin zinc oxide (ITZO), or the like.

When the second electrode CE is a transflective electrode or a reflective electrode, the second electrode CE may include Ag, Mg, Cu, Al, Pt, Pd, Au, Ni, Nd, Ir, Cr, Li, Ca, LiF/Ca, LiF/Al, Mo, Ti, Yb, W, or a compound or mixture including thereof (for example, AgMg, AgYb, or MgYb). Alternatively, the second electrode CE may have a multilayer structure including a reflective film or a transflective film formed using the above material and a transparent conductive film formed using indium tin oxide (ITO), indium zinc oxide (IZO), zinc oxide (ZnO), indium tin zinc oxide (ITZO), or the like. For example, the second electrode CE may include the above-described metal material, a combination of two or more metal materials selected from the above-described metal materials, or an oxide of the above-described metal materials.

The encapsulation layer TFE may be disposed on the second electrode CE to cover the light emitting element ED. The encapsulation layer TFE may include a plurality of thin films. For example, the encapsulation layer TFE may include inorganic films disposed on the second electrode CE and an organic film disposed between the inorganic films. The inorganic film may protect the light emitting element ED from moisture/oxygen, and the organic film may protect the light emitting element ED from foreign substances such as dust particles.

The input detection part TP may include a first detection insulating layer IL1, a second detection insulating layer IL2, and a third detection insulating layer IL3. The input detection part TP may include at least one conductive layer disposed on the detection insulating layers. The input detection part TP may include a first conductive layer CDL1 and a second conductive layer CDL2.

The first detection insulating layer IL1 may be disposed on the encapsulation layer TFE. The first detection insulating layer IL1 may include at least one inorganic insulating layer. The first detection insulating layer IL1 may be in contact with the encapsulation layer TFE. Alternatively, the first detection insulating layer IL1 may be omitted, and in this case, the first conductive layer CDL1 may be in contact with the encapsulation layer TFE.

The first conductive layer CDL1 may be disposed on the first detection insulating layer IL1. The first conductive layer CDL1 may include a plurality of first conductive patterns. The plurality of first conductive patterns may be disposed on the first detection insulating layer IL1. The second detection insulating layer IL2 may be disposed on the first detection insulating layer IL1 to cover at least a portion of the first conductive layer CDL1.

The second conductive layer CDL2 may be disposed on the second detection insulating layer IL2. The second conductive layer CDL2 may include a plurality of second conductive patterns. A plurality of second conductive patterns may be disposed on the second detection insulating layer IL2. Each of the plurality of second conductive patterns may be connected to a plurality of first conductive patterns through a contact hole formed in the second detection insulating layer IL2.

Each of the plurality of first conductive patterns of the first conductive layer CDL1 and the plurality of second conductive patterns of the second conductive layer CDL2 may be disposed to correspond to a light shielding area NLA. Each of the plurality of first conductive patterns of the first conductive layer CDL1 and the plurality of second conductive patterns of the second conductive layer CDL2 may correspond to a mesh pattern.

A third detection insulating layer IL3 may be disposed on the second detection insulating layer IL2 and may cover the second conductive layer CDL2. Each of the second detection insulating layer IL2 and the third detection insulating layer IL3 may include an inorganic insulating layer or an organic insulating layer.

Each of the first conductive layer CDL1 and the second conductive layer CDL2 may have a single layer structure or a multilayer structure laminated along the third direction DR3. The single layer conductive layer CDL1 or CDL2 may include a metal layer or a transparent conductive layer. The metal layer may include molybdenum, silver, titanium, copper, aluminum, or an alloy thereof. The transparent conductive layer may include a transparent conductive oxide such as indium tin oxide (ITO), indium zinc oxide (IZO), zinc oxide (ZnO), and indium zinc tin oxide (IZTO). In addition, the transparent conductive layer may include a conductive polymer such as poly(3,4-ethylenedioxythiophene) (PEDOT), a metal nanowire, graphene, or the like.

The conductive layers CDL1 and CDL2 with a multilayer structure may include metal layers. The metal layers may have, for example, a three-layer structure of titanium (Ti)/aluminum (Al)/titanium (Ti). The conductive layers CDL1 and CDL2 with a multilayer structure may include at least one metal layer and at least one transparent conductive layer.

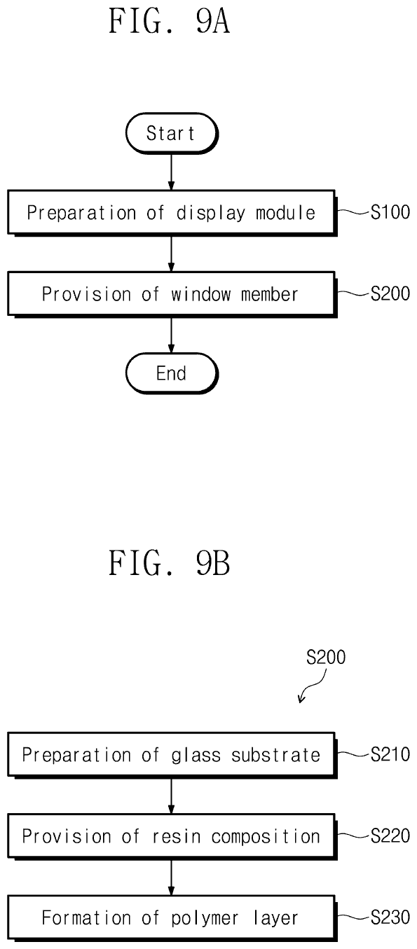

An electronic apparatus of an embodiment may be manufactured by a method for manufacturing an electronic apparatus of an embodiment. FIGS. 9A and 9B are flowcharts illustrating a method for manufacturing an electronic apparatus according to an embodiment. FIGS. 10A to 10E are schematic diagrams illustrating steps for manufacturing an electronic apparatus according to an embodiment. Hereinafter, in the description of FIGS. 9A to 10E, any content that overlaps with the content described with reference to FIGS. 1 to 8 will not be described again, and differences will be mainly described.

Referring to FIG. 9A, a method for manufacturing an electronic apparatus of an embodiment may include a step of preparing a display module (S100) and a step of providing a window member on the display module (S200). Referring to FIG. 9B, the step of providing a window member (S200) may include a step of preparing a glass substrate (S210), a step of providing a resin composition (S220), and a step of forming a polymer layer (S230).

Referring to FIG. 10A, a glass substrate GL may be provided on a carrier member CF. Before providing the resin composition COP (FIG. 10B), plasma LS treatment may be performed on one side of the glass substrate GL. During the plasma LS treatment, nitrogen plasma (N₂ plasma) may be provided. One side of the glass substrate GL may be a side on which the resin composition COP (FIG. 10B) is provided. The carrier member CF is provided for forming the window members WM and WM-1 to WM-7 (FIGS. 6 and 7A to 7G), and any member that facilitates the formation of the window member WM (FIGS. 6 and 7A to 7G) may be used without limitation and is not limited to any one embodiment.

Referring to FIG. 10B, the resin composition COP may be provided on the glass substrate GL. The resin composition COP may be provided by an inkjet printing method or a dispensing method. In FIG. 10B, the resin composition COP is illustrated as being provided through a nozzle NZ, but the device for providing the resin composition COP is not limited thereto.

The resin composition COP according to an embodiment may include a polyisocyanate, a polyol, an acrylate containing a cycloalkyl group, and a photoinitiator. The resin composition COP including the polyisocyanate, a polyol, the acrylate containing a cycloalkyl group, and the photoinitiator may be photocured to form a polymer layer RN (FIGS. 6 and 7A to 7G). The polymer layer RN (FIGS. 6 and 7A to 7G) formed from the resin composition COP according to an embodiment may satisfy the hardness, elastic modulus, indentation depth, and creep value described above.

The polymer layer RN (FIGS. 6 and 7A to 7G) formed by photocuring the resin composition COP according to an embodiment may include a polyether polyurethane acrylate-containing resin. The polymer layer RN (FIGS. 6 and 7A to 7G) formed by photocuring the resin composition COP according to an embodiment may include a polyether moiety, a polyurethane moiety, and a moiety derived from the acrylate.

The difference in refractive index of each of the polyurethane and the acrylate including a cycloalkyl group, included in the resin composition COP according to an embodiment and the refractive index of the glass substrate may be about 0.3 or less. For example, the refractive index of each of the polyurethane and the acrylate including a cycloalkyl group may be about 1.2 or more and about 1.8 or less, about 1.3 or more and about 1.7 or less, or about 1.4 or more and about 1.5 or less. Accordingly, the difference in refractive index of the polymer layer RN (FIGS. 6 and 7A to 7G) formed from the resin composition COP including the polyisocyanate, polyol and the acrylate including a cycloalkyl group and the refractive index of the glass substrate may be about 0.3 or less.

The polyisocyanate may include at least one among methylene diphenyl diisocyanate (MDI), hexamethylene diisocyanate, or isophorone diisocyanate. Optionally a polycaprolactone (PCL) may be present.

Methylene diphenyl diisocyanate exhibits excellent flexibility, and a polymer layer RN (FIGS. 6 and 7A to 7G) formed from the resin composition COP containing methylene diphenyl diisocyanate may exhibit excellent folding reliability and excellent impact resistance. Polycaprolactone has a refractive index of about 1.463 and exhibits excellent flexibility and elasticity, and the polymer layer RN (FIGS. 6 and 7A to 7G) formed from the resin composition COP containing polycaprolactone may exhibit excellent folding reliability and excellent impact resistance.

The polymer layer RN (FIGS. 6 and 7A to 7G) formed from the resin composition COP including the polyisocyanate, polyol, and acrylate having a cycloalkyl group may exhibit excellent folding reliability at low temperatures (for example, about −20° C. and about −5° C.). Since the polymer layer RN (FIGS. 6 and 7A to 7G), which is formed from the resin composition COP, includes a urethane moiety, crack occurrence and buckling defect occurrence may be minimized (or prevented) during folding at low temperatures. The excellent reliability at low temperatures may be confirmed through a low-temperature operating life test (LtoL).

For example, in the resin composition COP according to an embodiment, methylene diphenyl diisocyanate may be included as a reactant to provide the polyurethane. Below are the structural formulas of methylene diphenyl diisocyanate, hexamethylene diisocyanate, isophorone diisocyanate, and polycaprolactone. In the structural formula of polycaprolactone below, n2 may be an integer of 10 or more and 1000 or less.

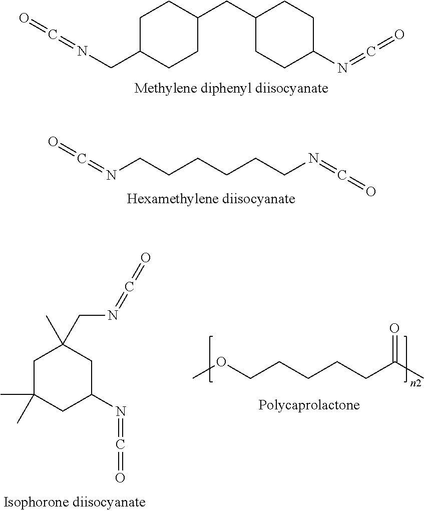

Based on 100 wt % of the total weight of the resin composition COP, the weight of the polyisocyanate may be about 1 wt % or more and about 10 wt % or less. Based on 100 wt % of the total weight of the resin composition COP, the polymer layer RN (FIGS. 6 and 7A to 7G) formed from the resin composition COP including polyisocyanate in a weight of about 1 wt % or more and about 10 wt % or less may exhibit excellent folding reliability and excellent impact resistance. In contrast, based on 100 wt % of the total weight of the resin composition, the polymer layer formed from the resin composition including polyisocyanate in a weight of less than about 1 wt % is not easy in repeating folding and unfolding. Based on 100 wt % of the total weight of the resin composition, the polymer layer formed from the resin composition including polyisocyanate in a weight of more than about 10 wt % is weak to external impact.

The acrylate including a cycloalkyl group may have a relatively high glass transition temperature. In the acrylate including a cycloalkyl group, the cycloalkyl group may be a condensed ring in which a plurality of cycloalkyl groups are condensed. The acrylate including a cycloalkyl group may include a moiety having high toughness. The acrylate including a cycloalkyl group may include isobornyl acrylate (IBOA). Isobornyl acrylate may have a glass transition temperature of about 94° C. and a refractive index of about 1.476. The polymer layer RN (FIGS. 6 and 7A to 7G) formed from the resin composition COP including isobornyl acrylate may exhibit excellent impact resistance and excellent adhesion. In addition, the polymer layer RN (FIGS. 6 and 7A to 7G) formed from the resin composition COP including isobornyl acrylate may exhibit excellent reliability because shrinkage is minimized in high-temperature and high-humidity environment. The polymer layer RN (FIGS. 6 and 7A to 7G) exhibiting excellent adhesiveness may prevent peeling during repeated folding and unfolding. The structural formula of isobornyl acrylate is shown below.

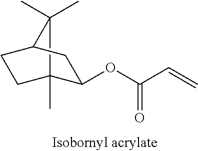

Based on 100 wt % of the total weight of the resin composition COP, the weight of the acrylate including a cycloalkyl group may be about 50 wt % or more and about 80 wt % or less. Based on 100 wt % of the total weight of the resin composition COP, the polymer layer RN (FIGS. 6 and 7A to 7G) formed from the resin composition COP including the acrylate including a cycloalkyl group in a weight of about 50 wt % or more and about 80 wt % or less may exhibit excellent folding reliability and excellent impact resistance.

The polymer layer RN (FIGS. 6 and 7A to 7G) formed from the resin composition COP including the photoinitiator may exhibit excellent durability. In addition, the photoinitiator may promote curing during the curing of the resin composition COP, thereby improving process efficiency.

The photoinitiator may include at least one of 1-hydroxy cyclohexyl-phenylketone or N,N,N′,N′-tetramethyl methanediamine. The 1-hydroxy cyclohexyl-phenylketone may be Irgacure 184. When the resin composition COP is photocured, a polymerization reaction may occur, and the polymer layer RN (FIGS. 6 and 7A to 7G) may be formed through the polymerization reaction. N,N,N′,N′-tetramethyl methanediamine may also serve as a catalyst that promotes the initiation of the polymerization reaction. Below are the structural formulas of 1-hydroxy cyclohexyl-phenylketone and N,N,N′,N′-tetramethyl methanediamine:

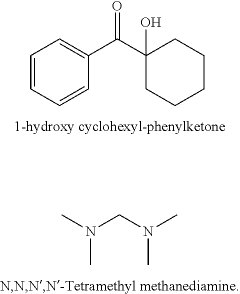

Based on 100 wt % of the total weight of the resin composition COP, the weight of the photoinitiator may be about 1 wt % or more and about 10 wt % or less. For example, based on 100 wt % of the total weight of the resin composition COP, the weight of the photoinitiator may be about 3 wt % or more and about 10 wt % or less. Alternatively, based on 100 wt % of the total weight of the resin composition COP, the weight of the photoinitiator may be about 1 wt % or more and about 5 wt % or less.

The resin composition COP may include a plurality of photoinitiators. When the resin composition COP includes a plurality of photoinitiators, different photoinitiators may be activated by ultraviolet light having different central wavelengths. The photoinitiator includes at least one of 1-hydroxy cyclohexyl-phenylketone or N,N,N′,N′-tetramethyl methanediamine, and may further include materials described below.

For example, the photoinitiator may include at least one of 2,2-dimethoxy-1,2-diphenylethan-1-one, 2-hydroxy-2-methyl-1-phenyl-1-propanone, 2-hydroxy-1-[4-(2-hydroxyethoxy)phenyl]-2-methyl-1-propanone, or 2-hydroxy-1-{4-[4-(2-hydroxy-2-methyl-propionyl)-benzyl]-phenyl}-2-methylpropan-1-one.

In addition, the photoinitiator may include at least one of 2-methyl-1-[4-(methylthio)phenyl]-2-morpholinopropan-1-one, 2-benzyl-2-dimethylamino-1-(4-morpholinophenyl)-butanone-1, 2-dimethylamino-2-(4-methyl-benzyl)-1-(4-morpholin-4-yl-phenyl)-butan-1-one, 2,4,6-trimethylbenzoyl-diphenylphosphine oxide, ethyl(2,4,6-trimethylbenzoyl)phenyl phosphinate, phenyl bis(2,4,6-trimethylbenzoyl)-phosphine oxide, [1-(4-phenylsulfanylbenzoyl)heptylideneamino]benzoate, [1-[9-ethyl-6-(2-methylbenzoyl)carbazol-3-yl]ethylideneamino]acetate, or bis(2,4-cyclopentadienyl)bis[2,6-difluoro-3-(1-pyrryl)phenyl]titanium(IV).

In an embodiment, the resin composition COP may further include a polymeric polyol. The resin composition COP may exhibit excellent reliability in high-temperature and high-humidity environment by further including a polymeric polyol having a relatively high molecular weight. A resin composition containing a monomeric polyol having a relatively small molecular weight in a greater amount than a polymeric polyol having a relatively high molecular weight exhibits reduced reliability due to stains caused by outgassing in high-temperature and high-humidity environment. In contrast, the resin composition COP of an embodiment may exhibit excellent high-temperature and high-humidity reliability after curing by containing a polymeric polyol in a greater amount than a monomeric polyol.

In the resin composition COP, the polymeric polyol may include a polyether polyol, and the polyether polyol may include at least one of polytetramethylene ether glycol (PTMEG) or polypropylene glycol (PPG). In the resin composition COP, the polymeric polyol may include at least one of polytetramethylene ether glycol (PTMEG) or polypropylene glycol (PPG). The polypropylene glycol exhibits excellent flexibility, and the polymer layer RN (FIGS. 6 and 7A to 7G) formed from the resin composition COP containing polypropylene glycol may exhibit excellent elastic modulus and improved elongation. Below are the structural formulas of polytetramethylene ether glycol (PTMEG) and polypropylene glycol (PPG). In the structural formulas below, n3 and n4 may each independently be an integer of 10 or more and 1000 or less:

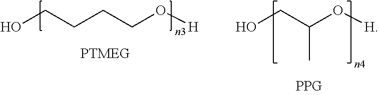

Based on 100 wt % of the total weight of the resin composition COP, the weight of the polymeric polyol may be about 1 wt % or more and about 10 wt % or less. When the resin composition COP includes a plurality of polymeric polyols, the weight of each of the plurality of polymeric polyols may be about 1 wt % or more and about 10 wt % or less based on 100 wt % of the total weight of the resin composition COP. Based on 100 wt % of the total weight of the resin composition COP, the resin composition COP including the polymeric polyol having a weight of about 1 wt % or more and about 10 wt % or less may exhibit excellent reliability in high-temperature and high-humidity environment.

The resin composition COP may further include at least one of an organic catalyst, a plasticizer, an antioxidant, or a coupling agent. The organic catalyst may promote the initiation of a polymerization reaction. The organic catalyst may include the aforementioned N,N,N′,N′-tetramethyl methanediamine. The coupling agent may be an adhesion promoter. The polymer layer RN (FIGS. 6 and 7A to 7G) formed from the resin composition COP including the coupling agent may exhibit excellent adhesion to the glass substrates GL and GL-1 to GL-4 (FIGS. 6 and 7A to 7G). The polymer layer RN (FIGS. 6 and 7A to 7G) formed from the resin composition COP including the plasticizer may exhibit excellent folding reliability when repeating folding and unfolding at low temperatures (for example, about −20° C.) and may exhibit excellent impact resistance.

The plasticizer may include a material represented by any one of X-1 to X-5 below, and the antioxidant may include a material represented by Y-1 below. The coupling agent may include at least one of a silane-containing coupling agent or a phosphoric acid-containing coupling agent. The coupling agent may include a material represented by any one of Z-1 to Z-5 below. In X-5 below, n1 and ml may each independently be an integer of 1 to 10. In Z-1 and Z-5 below, Rₐ and R_{b} may each independently be an aliphatic hydrocarbon having 1 to 60 carbon atoms or an aromatic hydrocarbon having 6 to 60 ring-forming carbon atoms. In the present specification, the aromatic hydrocarbon includes a monocyclic ring group and/or a polycyclic ring group. The aliphatic hydrocarbon includes a straight chain, a branched chain, and/or a cyclic chain.

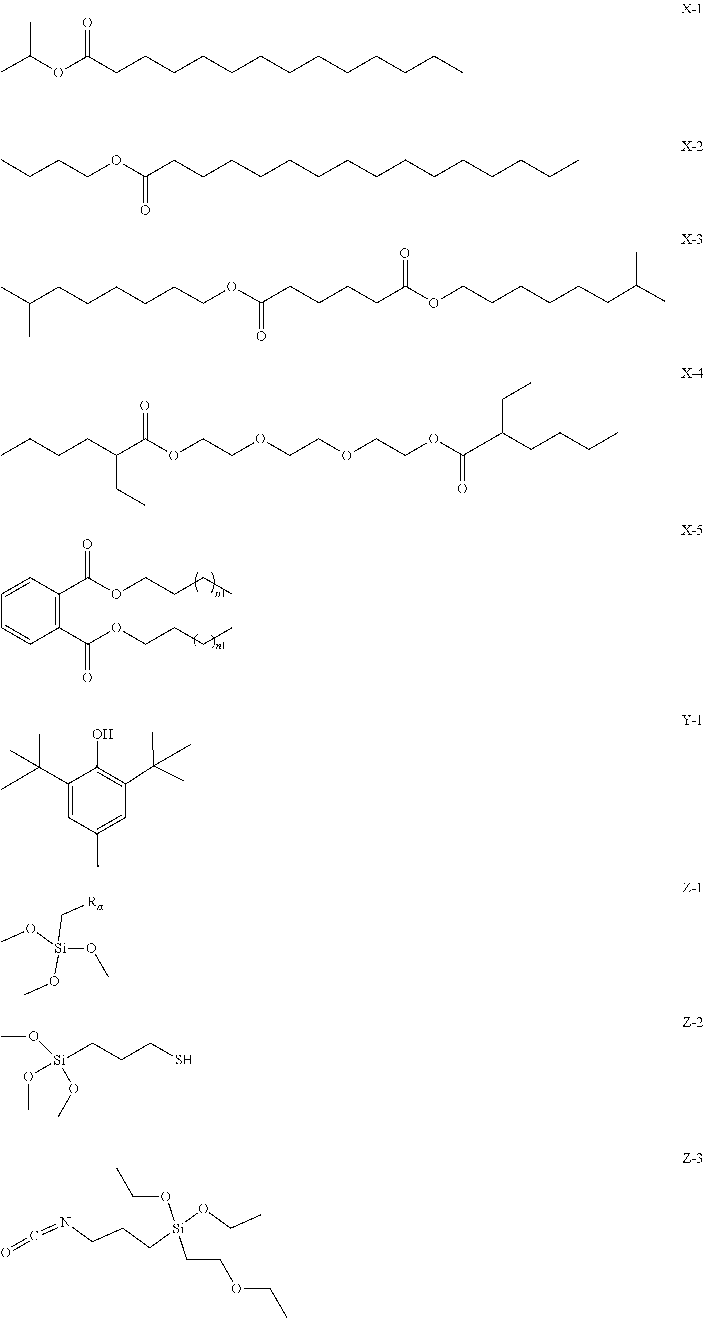

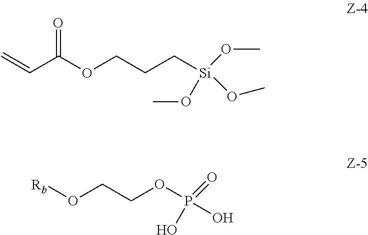

When the resin composition COP includes the plasticizer, the weight of the plasticizer may be about 1 wt % or more and about 20 wt % or less based on 100 wt % of the total weight of the resin composition COP. Alternatively, the weight of the plasticizer may be about 1 wt % or more and about 5 wt % or less based on 100 wt % of the total weight of the resin composition COP.

The resin composition COP may further include at least one of a monomer including a hydroxyl group, a monomer including an epoxy group, and a monomer having a relatively high refractive index. The resin composition COP may further include at least one of the first to sixteenth monomers. The first to sixteenth monomers may be represented by A-1 to A-16 below, respectively:

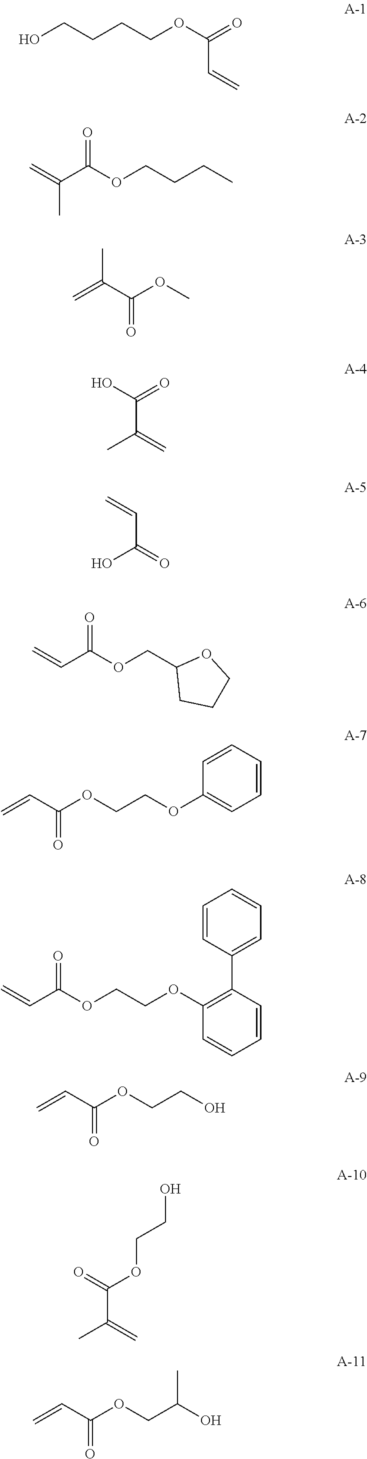

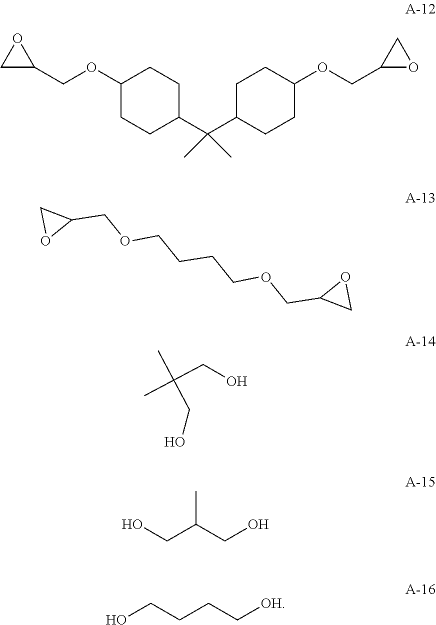

The first monomer represented by A-1 may have a refractive index of about 1.45, and the second monomer represented by A-2 may have a refractive index of about 1.42. The third monomer represented by A-3 may have a refractive index of about 1.41 and a glass transition temperature of about 105° C. or more and about 120° C. or less. The fourth monomer represented by A-4 may have a refractive index of about 1.431 and a glass transition temperature of about 228° C. The fifth monomer represented by A-5 may have a refractive index of about 1.42, and the sixth monomer represented by A-6 may have a refractive index of about 1.46.

The seventh monomer represented by A-7 may have a refractive index of about 1.518 and a glass transition temperature of about −22° C. The eighth monomer represented by A-8 may have a refractive index of about 1.576 and a glass transition temperature of about 107° C. The seventh monomer represented by A-7 is 2-phenoxyethyl acrylate, and the eighth monomer represented by A-8 is 2-phenylphenoxyethyl acrylate. The seventh and eighth monomers represented by A-7 and A-8, respectively, may be monomers exhibiting relatively high refractive indexes.

The ninth monomer represented by A-9 may have a refractive index of about 1.45 and a glass transition temperature of about −15° C. The tenth monomer represented by A-10 may have a refractive index of about 1.453 and a glass transition temperature of about 57° C. The eleventh monomer represented by A-11 may have a refractive index of about 1.44 and a glass transition temperature of about −7° C. The ninth monomer represented by A-9 is 2-hydroxyethyl acrylate, the tenth monomer represented by A-10 is 2-hydroxyethyl methacrylate, and the eleventh monomer represented by A-11 is 2-hydroxypropyl acrylate. The ninth to eleventh monomers represented by A-9 to A-11, respectively, are monomers containing a hydroxyl group, and the polymer layer RN (FIGS. 6 and 7A to 7G) formed from the resin composition COP containing the monomer containing a hydroxyl group exhibits excellent adhesion to the glass substrates GL and GL-1 to GL-4 (FIGS. 6 and 7A to 7G), so that peeling may be prevented during repeating folding and unfolding.

The twelfth monomer represented by A-12 may have a refractive index of about 1.51 and a glass transition temperature of about 136° C. The thirteenth monomer represented by A-13 may have a refractive index of about 1.453. The twelfth and thirteenth monomers represented by A-12 and A-13, respectively, are monomers containing an epoxy group, and the polymer layer RN (FIGS. 6 and 7A to 7G) formed from the resin composition COP containing a monomer containing an epoxy group may exhibit optical properties similar to those of the glass substrates GL and GL-1 to GL-4 (FIGS. 6 and 7A to 7G) and may exhibit excellent folding reliability. The polymer layer RN (FIGS. 6 and 7A to 7G) may exhibit transparency and refractive index similar to those of the glass substrates GL and GL-1 to GL-4 (FIGS. 6 and 7A to 7G).

The fourteenth monomer represented by A-14 is neopentyl glycol. The fifteenth monomer represented by A-15 is 2-methyl-1,3-propanediol. The sixteenth monomer represented by A-16 is 1,4-butanediol.

Referring to FIG. 10C, a roller RL and a substrate FM are provided on the resin composition COP provided on the glass substrate GL so as to form a preliminary polymer layer P-RN (FIG. 10D). The substrate FM may be flat and may be provided to flatten one surface of the preliminary polymer layer P-RN (FIG. 10D) spaced apart from the glass substrate GL. The substrate FM is placed on the resin composition COP provided on the glass substrate GL and the roller RL is moved on the substrate FM so that the preliminary polymer layer P-RN (FIG. 10D) having one flat surface may be formed. However, this is an illustration, and the target preliminary polymer layer P-RN (FIG. 10D) may be formed only with the nozzle NZ (FIG. 10B) without providing the roller RL and the substrate FM.

Referring to FIG. 10D, the preliminary polymer layer P-RN may be a layer covering the lower surface and the side surface of the glass substrate GL. Light LT may be provided to the preliminary polymer layer P-RN. The light LT may be ultraviolet light. The preliminary polymer layer P-RN may be cured by the light LT to form a polymer layer RN (FIG. 10E). In FIG. 10D, the light LT is illustrated as being provided to the preliminary polymer layer P-RN by transmitting the substrate FM, but an embodiment of the inventive concept is not limited thereto. Unlike what is illustrated, the light LT may be directly provided to the preliminary polymer layer P-RN.

The method for manufacturing an electronic apparatus of an embodiment, including a step of providing the light LT to the preliminary polymer layer P-RN to form a polymer layer RN (FIG. 10E) may exhibit excellent manufacturing efficiency. The method for manufacturing an electronic apparatus, including a step of providing heat to the composition to form a polymer layer exhibits a long process time and low manufacturing efficiency. In contrast, the method for manufacturing an electronic apparatus of an embodiment, includes a step of forming a polymer layer RN (FIG. 10E) through a curing process by light LT and may exhibit excellent manufacturing efficiency.

Referring to FIG. 10E, a laser may be irradiated to the polymer layer RN from a laser irradiation device SR. The polymer layer RN may be cut by irradiating the laser so that the polymer layer RN has a target size and/or shape. After the laser irradiation, the window member WM-3 illustrated in FIG. 7C may be formed. When forming the window members WM-4, WM-5, and WM-7 illustrated in FIGS. 7D, 7E, and 7G, manufacturing steps similar to those described with reference to FIGS. 10A to 10E may be performed. The manufacturing method described with reference to FIGS. 10A to 10E may be performed when forming the window members WM-3, WM-4, WM-5, and WM-7 (FIGS. 7C to 7E and FIG. 7G) in which the polymer layer RN is disposed to surround the lower surface G_DFa (FIG. 7C) of the glass substrate GL-2.

Unlike what is illustrated, the laser irradiation step may be omitted. Although not shown, a plasma treatment may be performed on one surface of the polymer layer RN (FIGS. 6 and 7A to 7G) spaced apart from the glass substrates GL and GL-1 to GL-4 (FIGS. 6 and 7A to 7G). The polymer layer RN including the plasma-treated one surface may have improved adhesion to an adjacent element (for example, a protective layer PL and/or glass substrates GL and GL-1 to GL-4 (FIGS. 6 and 7A to 7G)).

FIGS. 11A to 11F are schematic diagrams showing steps for manufacturing an electronic apparatus according to another embodiment of the inventive concept. In the description of FIGS. 11A to 11F below, any content that overlaps with that described with reference to FIGS. 1 to 10E will not be described again, and differences will be mainly described.

Referring to FIG. 11A, a glass substrate GL-4 may be provided on a carrier member CF. Plasma LS treatment may be performed on one surface of the glass substrate GL-4 prior to providing a resin composition COP (FIG. 11B). One surface of the glass substrate GL may be the surface on which the resin composition COP (FIG. 11B) is provided.

Referring to FIGS. 11B to 11D, a resin composition COP may be provided on the glass substrate GL-4 through a nozzle NZ, and a preliminary polymer layer P-RN having a flat surface may be formed using a roller RL and a substrate FM. The preliminary polymer layer P-RN may surround the upper surface and side surface of the glass substrate GL-4.

Referring to FIG. 11D and FIG. 11E, light LT may be irradiated to the preliminary polymer layer P-RN to form a polymer layer RN. After the irradiation of the light LT, a plasma LS treatment may be performed on one surface of the polymer layer RN spaced apart from the glass substrate GL-4. The polymer layer RN including the plasma-treated surface may have improved adhesion to an adjacent element (for example, a protective layer PL and/or glass substrates GL and GL-1 to GL-4 (FIGS. 6 and 7A to 7G)).

Referring to FIG. 11F, a printing layer BM and a protective layer PL are provided on the polymer layer RN, and a laser may be irradiated from a laser irradiation device SR. The laser may be irradiated to the polymer layer RN, the printing layer BM, and the protective layer PL. However, this is an illustration, and unlike what is illustrated, the printing layer BM and the protective layer PL may be provided after the polymer layer RN is exposed to a laser. After the laser is irradiated, the window member WM-6 illustrated in FIG. 7F may be formed. When forming the window members WM, WM-1, WM-2, and WM-5 illustrated in FIGS. 6, 7A, 7B, and 7E, similar manufacturing steps as described with reference to FIGS. 11A to 11F may be performed. The manufacturing method described with reference to FIGS. 11A to 11F may be performed when forming the window members WM, WM-1, WM-2, WM-5, and WM-6 (FIGS. 6, 7A, 7B, and 7E) in which the polymer layer RN is disposed to surround the upper surface G_UF (FIG. 6) of the glass substrate GL.

Hereinafter, with reference to comparative examples and examples, the resin composition and the polymer layer according to an embodiment of the inventive concept will be specifically described. In addition, the examples shown below are examples to help understanding of the inventive concept, and the scope of the inventive concept is not limited thereto.

Table 2 below shows the evaluation of the window members of the Comparative Examples and shows simulation results. The window members of Comparative Examples R-A and R-B include a glass substrate and a polymer layer disposed on the glass substrate as shown in FIG. 6, and the polymer layer is formed from a resin composition including a material as shown in Table 1 below. In Table 1, the first component is a main component, and the second component is provided as an additive. In the window member of Comparative Example R-A, the polymer layer includes a silicone acrylate hybrid resin, and in the window member of Comparative Example R-B, the polymer layer includes a polyester polyurethane acrylate resin. In the window member of Comparative Example R-A, the resin composition forming the polymer layer is provided with two materials as the first component and five materials as the second component. In the window member of Comparative Example R-B, the resin composition forming the polymer layer is provided with six materials as the first component and five materials as the second component. In the window member of Comparative Example R-A, the polymer layer is formed through an ultraviolet light curing process, and in the window member of Comparative Example R-B, the polymer layer is formed through a thermal curing process.

TABLE 1

| | Comparative Example R-A | | | Comparative Example R-B | | |
|---|---|---|---|---|---|---|
| Division | Material | Amount | | Material | Amount | |
| First component | 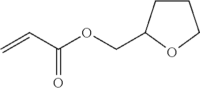 Tetrahydrofurfuryl methacrylate | 50-70 | wt % | 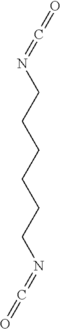 [SMILES: O=C=NCCCCCCN=C=O] | 25-40 | wt % |
| | | | | Hexamethylene | | |
| | | | | diisocyanate | | |
| | 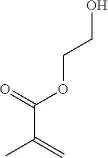 | 1-10 | wt % | 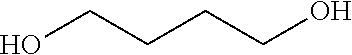 A-16 | 2-10 | wt % |
| | 2-hydroxethyl | | | | | |
| | methyacrylate | | | | | |
| | | | | 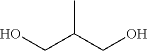 | 5-15 | wt % |
| | | | | A-15 | | |
| | | | | 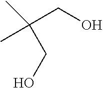 | 5-15 | wt % |
| | | | | A-14 | | |
| | | | | 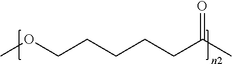 | 0.1-10 | wt % |
| | | | | Polycaprolactone | | |
| | | | | 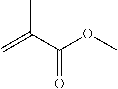 | 2-10 | wt % |
| | | | | A-3 | | |
| Second component | 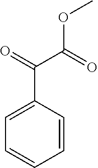 | 20-40 | wt % | 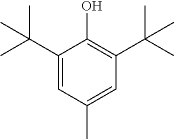 [SMILES: Cc1cc(C(C)(C)C)c(O)c(C(C)(C)C)c1] Y-1 | 0.1-5 | wt % |
| | 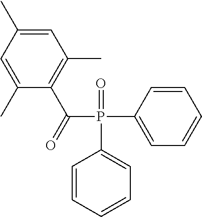 [SMILES: Cc1cc(C)c(C(=O)P(=O)(c2ccccc2)c2ccccc2)c(C)c1] | 1-10 | wt % | 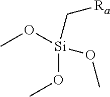 Z-1 | 0.1-5 | wt % |
| | DAROCUR TPO | | | | | |
| | 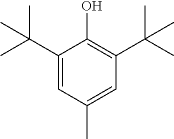 [SMILES: Cc1cc(C(C)(C)C)c(O)c(C(C)(C)C)c1] Y-1 | 0.1-5 | wt % | 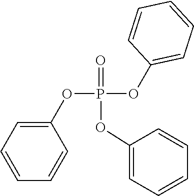 [SMILES: O=P(Oc1ccccc1)(Oc1ccccc1)Oc1ccccc1] | 0.1-5 | wt % |
| | | | | F-1 | | |
| | 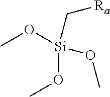 Z-1 | 0.1-5 | wt % | 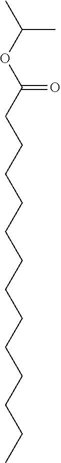 [SMILES: CCCCCCCCCCCCCC(=O)OC(C)C] | 20-40 | wt % |
| | | | | X-1 | | |
| | 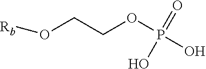 Z-5 | 0.1-5 | wt % | 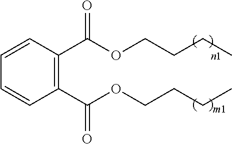 | 0.5-10 | wt % |
| | | | | X-5 | | |

In Table 1, Rₐ and R_{b} are each independently aliphatic hydrocarbon having 1 to 60 carbon atoms or aromatic hydrocarbon having 6 to 60 ring-forming carbon atoms. In polycaprolactone, n2 is an integer of 10 to 1000. F-1 is a plasticizer or a flame retardant. In X-5, n1 and ml are each independently an integer of 1 to 10.

The window member of Comparative Example R-A includes the polymer layer of the Comparative Example, and the polymer layer is formed from a resin composition that does not provide a polyurethane and an acrylate containing a cycloalkyl group. The window member of Comparative Example R-B includes the polymer layer of the Comparative Example, and the polymer layer is formed from a resin composition that does not include an acrylate containing a cycloalkyl group.

In Table 2 below, the adhesive strength is obtained according to ASTM D3359, and the adhesive strength is classified from 0B to 5B in ASTM D3359, where 0B indicates relatively low adhesive strength, and 5B indicates relatively high adhesive strength. Low-temperature folding is a low-temperature operating life test (LtoL) conducted at a temperature of about −20° C. and checks whether cracks occur when repeating folding and unfolding. In Comparative Example R-A in Table 2, “2F/2F” means that cracks occurred in two samples. In Comparative Example R-B in Table 2, “0F/2F” means that no sample among the two samples exhibited cracks. The surface quality was evaluated using 3D-LLM. The value on the left in “/” in the surface quality is an average value, and the value on the right is a dispersion value.

TABLE 2

| | Comparative | Comparative |
|---|---|---|
| | Example R-A | Example R-B |
| Adhesive strength | 5B | 5B |
| Low-temperature | 2F/2F | 0F/2F |
| folding (−20° C.) | | |
| Surface quality | 3.0/1.1 | 0.8/0.3 |
| (average/dispersion) | | |

Referring to Table 2, it can be found that the polymer layers in the window members of Comparative Examples R-A and R-B exhibit good adhesive strength. It can be found that the window member of Comparative Example R-A (with no polyurethane-forming components) exhibits reduced folding reliability and reduced surface quality. In the window member of Comparative Example R-A, the polymer layer is formed from a resin composition that does not contain a plasticizer and includes a silicone acrylate hybrid resin. Accordingly, the window member of Comparative Example R-A exhibits reduced folding reliability and reduced surface quality.

In the window member of Comparative Example R-B, the polymer layer includes a polyester polyurethane acrylate resin wherein the acrylate includes no cycloalkyl groups. The window member of Comparative Example R-B exhibits improved folding reliability and improved surface quality, but since the polymer layer is formed by a thermosetting process, low manufacturing efficiency is exhibited.

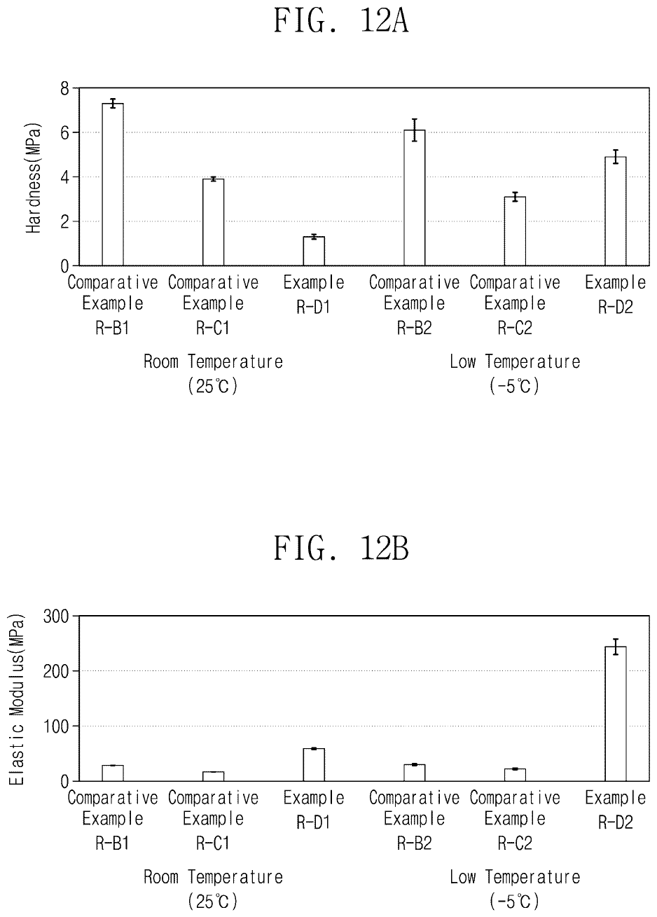

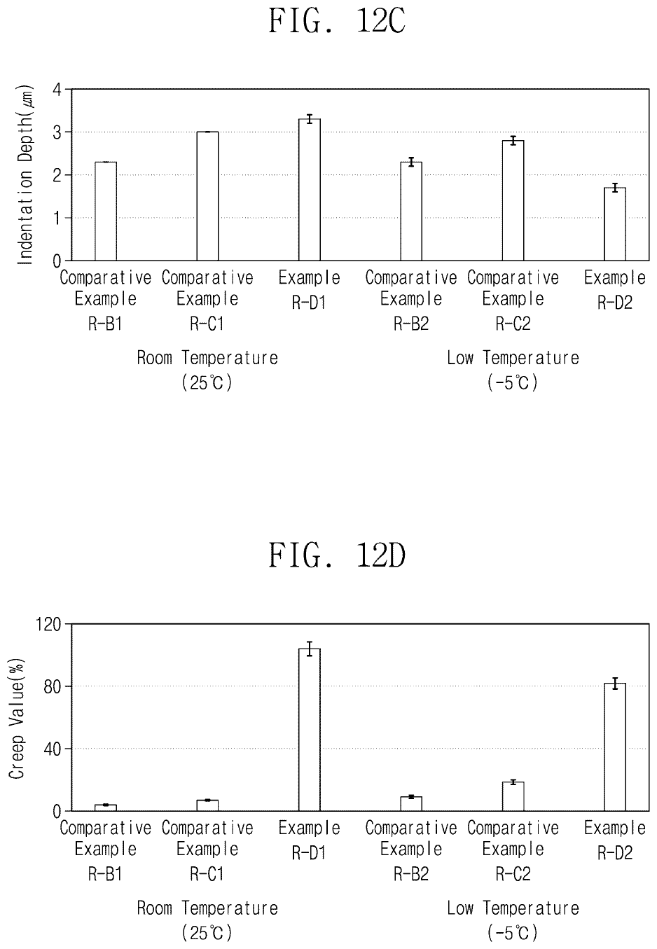

FIGS. 12A to 12D are graphs showing the hardness, elastic modulus, indentation depth, and creep value, respectively, measured by a nanoindentation tester in the window members of the Comparative Examples and the Examples, which are simulation values. In FIGS. 12A to 12D, the window members of the Comparative Examples include a glass substrate and a polymer layer disposed on the glass substrate, as illustrated in FIG. 6, and further include a primer layer having a thickness of about 1 m or less between the glass substrate and the polymer layer. In FIGS. 12A to 12D, the window members of the Examples include a glass substrate and a polymer layer disposed on the glass substrate, as illustrated in FIG. 6.

Comparative Example R-B1, Comparative Example R-C1, and Example R-D1 exhibit simulation values at a temperature of about 25° C. Comparative Example R-B2, Comparative Example R-C2, and Example R-D1 exhibit simulation values at a temperature of about −5° C.

Table 3 below shows the materials and contents included in the formation of the polymer layers in the window members of the Comparative Examples and Examples of FIGS. 12A to 12D. In FIGS. 12A to 12D, Comparative Examples R-B1 and R-B2 were formed from a resin composition including the same material as the polymer layer of Comparative Example R-B described above. The polymer layers of Comparative Examples R-C1 and R-C2 were formed from a resin composition including the material of Comparative Example R-C of Table 3. The polymer layers of Examples R-D1 and R-D2 were formed from a resin composition including the material of Example R-D of Table 3. The polymer layers of Comparative Examples R-C and Example R-D include a components for the formation of a polyether polyurethane acrylate resin, where the acrylate includes a cycloalkyl group (IBOA).

TABLE 3

| | Comparative Example R-C | | | Example R-D | | |
|---|---|---|---|---|---|---|
| Division | Material | Amount | | Material | Amount | |
| First component | 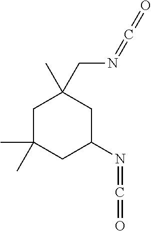 [SMILES: CC1(C)CC(N=C=O)CC(C)(CN=C=O)C1] Isophorone diisocyanate | 0.5-10 | wt % | 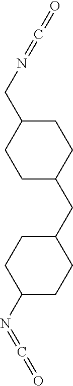 [SMILES: O=C=NCC1CCC(CC2CCC(N=C=O)CC2)CC1] | 1-10 | wt % |
| | | | | MDI | | |
| | 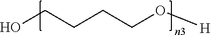 | 20-35 | wt % | 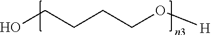 | 1-10 | wt % |
| | PTMEG | | | PTMEG | | |
| | 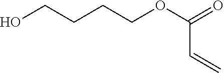 A-1 | 1-10 | wt % | 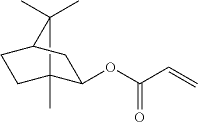 | 50-80 | wt % |
| | | | | IBOA | | |
| | 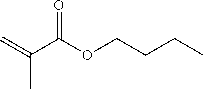 A-2 | 20-40 | wt % | 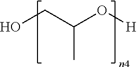 PPG | 1-10 | wt % |
| | 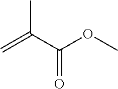 | 10-20 | wt % | | | |
| | A-3 | | | | | |
| | 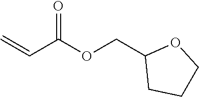 | 1-10 | wt % | | | |
| | A-6 | | | | | |
| Second component | 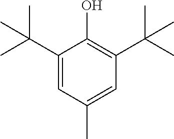 [SMILES: Cc1cc(C(C)(C)C)c(O)c(C(C)(C)C)c1] | 0.1-5 | wt % | 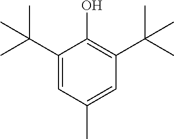 [SMILES: Cc1cc(C(C)(C)C)c(O)c(C(C)(C)C)c1] | 0.1-5 | wt % |
| | Y-1 | | | Y-1 | | |
| | 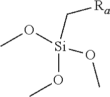 | 0.1-5 | wt % | 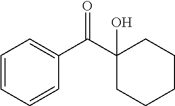 [SMILES: O=C(c1ccccc1)C1(O)CCCCC1] | 3-10 | wt % |
| | Z-1 | | | 1-hydroxy cyclohexyl- | | |
| | | | | phenylketone | | |
| | 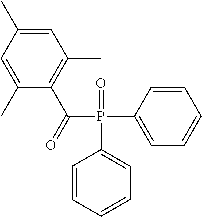 [SMILES: Cc1cc(C)c(C(=O)P(=O)(c2ccccc2)c2ccccc2)c(C)c1] | 1-10 | wt % | 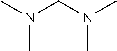 N,N,N′,N′- Tetramethyl methanediamine | 1-5 | wt % |
| | F-2 | | | | | |
| | 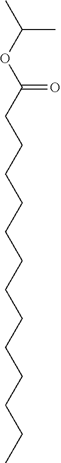 [SMILES: CCCCCCCCCCCCCC(=O)OC(C)C] | 1-20 | wt % | 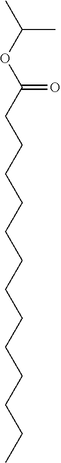 [SMILES: CCCCCCCCCCCCCC(=O)OC(C)C] | 1-20 | wt % |
| | X-1 | | | X-1 | | |
| | 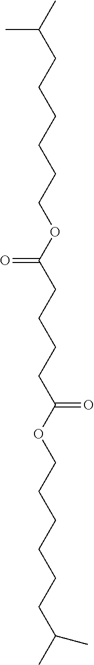 [SMILES: CC(C)CCCCCCOC(=O)CCCCC(=O)OCCCCCCC(C)C] | 1-10 | wt % | 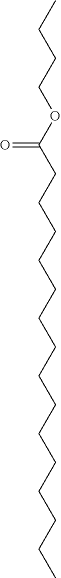 [SMILES: CCCCCCCCCCCCCCCC(=O)OCCCC] X-2 | 1-5 | wt % |
| | X-3 | | | | | |
| | | | | 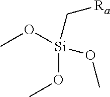 | 0.1-5 | wt % |
| | | | | Z-1 | | |

In Table 3, n3 and n4 are each independently an integer of 10 or more and 1000 or less. Rₐ is aliphatic hydrocarbon having 1 or more and 60 or less carbon atoms or aromatic hydrocarbon having 6 or more and 60 or less ring-forming carbon atoms. F-2 is a photoinitiator and is Omnirad TPO.

The window member of Comparative Example R-C includes the polymer layer of the Comparative Example, and the polymer layer is formed from a resin composition that does not include an acrylate containing a cycloalkyl group. In addition, the resin composition forming the polymer layer in Comparative Example R-C includes a relatively large amount of a monomer having a small molecular weight.

The window member of Example R-D includes the polymer layer according to an embodiment, and the polymer layer is formed from a resin composition including components to form a polyurethane (that is, MDI, PTMEG, and PPG), an acrylate containing a cycloalkyl group (that is, IBOA), and a photoinitiator (that is, 1-hydroxy cyclohexyl-phenylketone). In the resin composition forming the polymer layer of Example R-D, the weight of the polyisocyanate (MDI) is about 1 wt % or more and about 10 wt % or less, and the weight of the acrylate containing a cycloalkyl group is about 50 wt % or more and about 80 wt % or less, satisfying the weight ranges described above.

Table 4 below shows the hardness, elastic modulus, indentation depth, and creep value at about 25° C. of FIGS. 12A to 12D. Table 5 below shows the hardness, elastic modulus, indentation depth, and creep value at about −5° C. of FIGS. 12A to 12D. In Tables 4 and 5, the values listed on the right based on “±” represent measurement dispersion.

TABLE 4

| | | Comparative | Comparative | |
|---|---|---|---|---|
| | | Example R-B1 | Example R-C1 | Example R-D1 |
| Room | Hardness (MPa) | 7.3 ± 0.2 | 3.9 ± 0.1 | 1.3 ± 0.1 |
| temperature | Elastic Modulus (MPa) | 28.6 ± 0.3 | 16.6 ± 0.2 | 58.8 ± 1.7 |
| (25° C.) | Indentation depth (μm) | 2.3 ± 0.0 | 3.0 ± 0.0 | 3.3 ± 0.1 |
| | Creep value (%) | 4.0 ± 0.4 | 6.9 ± 0.4 | 104.0 ± 4.4 |

TABLE 5

| | | Comparative | Comparative | |
|---|---|---|---|---|
| | | Example R-B2 | Example R-C2 | Example R-D2 |
| Low | Hardness (MPa) | 6.1 ± 0.5 | 3.1 ± 0.2 | 4.9 ± 0.3 |
| temperature | Elastic Modulus (MPa) | 30.0 ± 1.3 | 22.1 ± 1.3 | 243.7 ± 14.1 |
| (−5° C.) | Indentation depth (μm) | 2.3 ± 0.1 | 2.8 ± 0.1 | 1.7 ± 0.1 |
| | Creep value (%) | 9.1 ± 0.9 | 18.6 ± 1.5 | 81.8 ± 3.5 |

Referring to Tables 4 and 5, it can be found that the polymer layers in the window members of Examples R-D1 and R-D2 satisfy the hardness, elastic modulus, indentation depth, and creep value according to an embodiment at room temperature and a low temperature. As described above, the polymer layers in the window members of Examples R-D1 and R-D2 are formed from the material included in Example R-D described in Table 3, and Example R-D includes components to form a polyurethane (a polyisocyanate and a polyol), an acrylate containing a cycloalkyl group, and a photoinitiator.

As described above, the polymer layers in the window members of Comparative Examples R-C1 and R-C2 are formed from the resin composition including the material included in Comparative Example R-C described in Table 3. It was confirmed through simulation that buckling occurs in Comparative Example R-C at a temperature of about −20° C. and stains occur in high-temperature and high-humidity environment.

Table 6 below shows the measurement results of the adhesive strength on the polymer layers for experimental examples with and without plasma treatment or with different plasma treatment speeds. The adhesive strength was measured by a universal testing machine (UTM). In Table 6, the polymer layers of Experimental Examples P-1 to P-4 were evaluated using the same material used in the evaluation of the polymer layer of Example R-D described in Table 3. The polymer layer of Experimental Example P-1 was not subjected to plasma treatment, and the polymer layers of Experimental Examples P-2 to P-4 were subjected to plasma treatment. Oxygen gas was used during plasma treatment. The polymer layers of Experimental Examples P-2 to P-4 had different plasma treatment speeds.

TABLE 6

| | Experimental | Experimental | | Experimental | | Experimental | |
|---|---|---|---|---|---|---|---|
| | Example P-1 | Example P-2 | | Example P-3 | | Example P-4 | |
| Plasma treatment rate | Untreated | 150 | mm/s | 100 | mm/s | 50 | mm/s |
| Adhesive strength | 32 gf/in | 463 | gf/in | 418 | gf/in | 434 | gf/in |

Referring to Table 6, it can be found that the polymer layers of Experimental Examples P-2 to P-4 exhibit improved adhesive strength compared to the polymer layer of Experimental Example P-1 without the plasma treatment. The polymer layers of Experimental Examples P-2 to P-4 exhibit excellent adhesive strength by performing plasma treatment. Accordingly, it can be found that the method for manufacturing an electronic apparatus of an embodiment, including the plasma treatment step of the polymer layer exhibits excellent processability, and the electronic apparatus manufactured by the method for manufacturing an electronic apparatus of an embodiment exhibits excellent reliability.

The electronic apparatus of an embodiment may include a window member disposed on a display module including a folding part. The window member may include a glass substrate and a polymer layer. The polymer layer may be disposed on at least one of the upper surface and lower surface of the glass substrate. The polymer layer may be formed from a resin composition including components to form polyurethane (i.e., a polyisocyanate and a polyol), an acrylate including a cycloalkyl group, and a photoinitiator. Accordingly, the polymer layer may exhibit excellent folding reliability, excellent impact resistance, and excellent display quality. In an embodiment, the electronic apparatus including the polymer layer may exhibit excellent impact resistance without increasing thickness, excellent folding reliability, and excellent display quality.

The method for manufacturing an electronic apparatus of an embodiment may include a forming step of a polymer layer by photocuring a resin composition. Accordingly, the method for manufacturing an electronic apparatus of an embodiment may exhibit excellent manufacturing efficiency and excellent processability.

An electronic apparatus of an embodiment may exhibit excellent folding reliability, excellent impact resistance, and excellent display quality by including a polymer layer formed from a resin composition including a polyisocyanate, polyol, an acrylate containing a cycloalkyl group, and a photoinitiator.

A method for manufacturing an electronic apparatus of an embodiment may exhibit excellent manufacturing efficiency and excellent processability by including a step of forming a polymer layer by photocuring a resin composition.

In the above, description has been made with reference to embodiments of the inventive concept, but those skilled or of ordinary skill in the art may understand that various modifications and changes may be made to the inventive concept insofar as such modifications and changes do not depart from the spirit and technical scope of the inventive concept set forth in the claims to be described later.

Therefore, the technical scope of the inventive concept is not to be limited to the contents stated in the detailed description of the specification, but should be determined by the claims.

What is claimed is:

1. An electronic apparatus comprising: a display module comprising a folding part, a first non-folding part adjacent to one side of the folding part, and a second non-folding part adjacent to the other side of the folding part; and a window member disposed on the display module,
wherein the window member comprises: a glass substrate comprising a lower surface and an upper surface facing the lower surface in a thickness direction; and a polymer layer disposed on at least one of the lower surface or the upper surface and comprising a polymer derived from a resin composition,
wherein the resin composition comprises a polyisocyanate, a polyol, an acrylate comprising a cycloalkyl group, and a photoinitiator.

2. The electronic apparatus of claim 1,
wherein the polymer layer has a hardness of about 1.0 megapascal or more and about 10.0 megapascals or less, an elastic modulus of about 10 megapascals or more and about 300 megapascals or less, an indentation depth of about 1.0 micrometer or more and about 5.0 micrometers or less, and a creep value of about 2.0% or more and about 150.0% or less, and
the hardness, the elastic modulus, the indentation depth, and the creep value are measured by a nano indentation tester at temperatures of about −5° C. and about 25° C.

3. The electronic apparatus of claim 1,
wherein the polyisocyanate comprises at least one of methylene diphenyl diisocyanate, hexamethylene diisocyanate, or isophorone diisocyanate,
the polyol comprises a polyether polyol, and the polyether polyol comprises at least one of polytetramethylene ether glycol or polypropylene glycol,
the acrylate comprises isobornyl acrylate, and
the photoinitiator comprises at least one of 1-hydroxy cyclohexyl-phenyl ketone or N,N,N′,N′-tetramethyl methanediamine.

4. The electronic apparatus of claim 1, wherein the resin composition further comprises a polycaprolactone.

5. The electronic apparatus of claim 1,
wherein the resin composition further comprises at least one of an organic catalyst, a plasticizer, an antioxidant, or a coupling agent,
the plasticizer comprises a material represented by any one of X-1 to X-5,
the antioxidant comprises a material represented by Y-1, and
the coupling agent comprises at least one of a silane-containing coupling agent or a phosphoric acid-containing coupling agent: 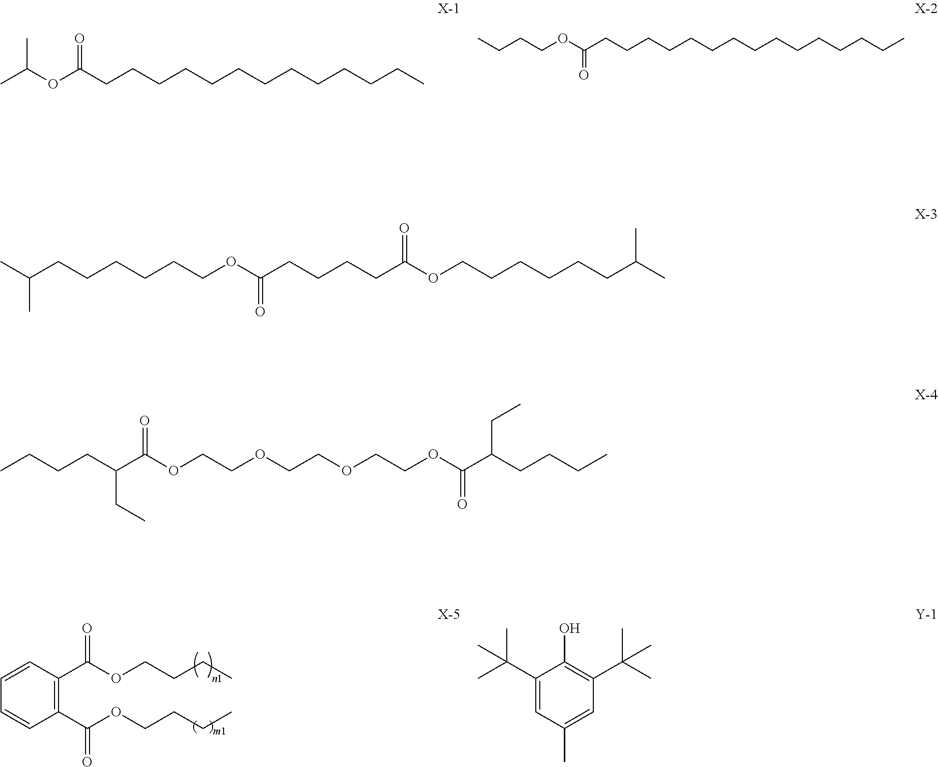
wherein in X-5, n1 and ml are each independently an integer of 1 to 10.

6. The electronic apparatus of claim 1, wherein the resin composition further comprises at least one of first to sixteenth monomers represented by A-1 to A-16, respectively:

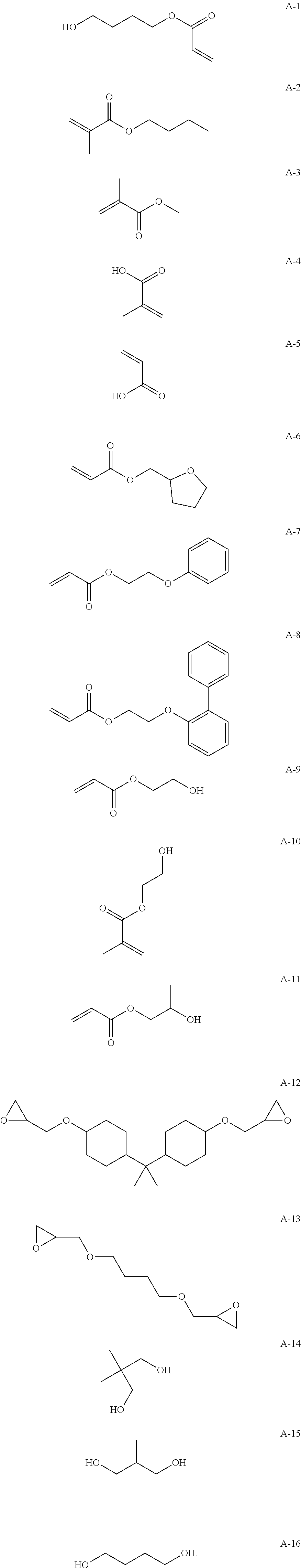

7. The electronic apparatus of claim 1, wherein a difference between a refractive index of the glass substrate and a refractive index of the polymer layer is about 0.3 or less.

8. The electronic apparatus of claim 1, wherein the window member further comprises an adhesive layer directly disposed on one surface of the polymer layer spaced apart from the glass substrate.

9. The electronic apparatus of claim 1,
wherein the glass substrate comprises a side surface disposed between the upper surface and the lower surface, and
the polymer layer surrounds at least one of the upper surface, the lower surface, or the side surface.

10. The electronic apparatus of claim 1,
wherein the glass substrate is divided into a first portion overlapping the folding part, a second portion overlapping the first non-folding part, and a third portion overlapping the second non-folding part, and
a thickness of the first portion is smaller than a thickness of the second portion and a thickness of the third portion.

11. The electronic apparatus of claim 1,
wherein the polymer layer is divided into a fourth portion overlapping the folding part, a fifth portion overlapping the first non-folding part, and a sixth portion overlapping the second non-folding part, and
a thickness of the fourth portion is greater than a thickness of the fifth portion and a thickness of the sixth portion.

12. The electronic apparatus of claim 1, further comprising at least one of a processor, a power module, or a memory.

13. A method for manufacturing an electronic apparatus, the method comprising:
preparing a display module comprising a folding part, a first non-folding part adjacent to one side of the folding part, and a second non-folding part adjacent to the other side of the folding part; and
providing a window member comprising: a glass substrate comprising a lower surface and an upper surface facing the lower surface in a thickness direction, and a polymer layer disposed on at least one of the lower surface or the upper surface and comprising a polymer derived from a resin composition on the display module,
wherein the resin composition comprises a polyisocyanate, a polyol, an acrylate comprising a cycloalkyl group, and a photoinitiator, and
the providing of the window member comprises:
preparing the glass substrate;
providing the resin composition on the glass substrate to form a preliminary polymer layer; and
irradiating light on the preliminary polymer layer to form the polymer layer.

14. The method for manufacturing an electronic apparatus of claim 13, wherein in forming the polymer layer, plasma treatment is performed on the polymer layer after irradiating the light.

15. The method for manufacturing an electronic apparatus of claim 13, wherein the resin composition is provided by an inkjet printing method or a dispensing method.

16. The method for manufacturing an electronic apparatus of claim 13,
wherein the polyisocyanate comprises at least one of methylene diphenyl diisocyanate, hexamethylene diisocyanate, isophorone diisocyanate, or polycaprolactone,
the acrylate comprises isobornyl acrylate, and
the photoinitiator comprises at least one of 1-hydroxy cyclohexyl-phenyl ketone or N,N,N′,N′-tetramethyl methanediamine.

17. The method for manufacturing an electronic apparatus of claim 13,
wherein a weight of the polyisocyanate is about 1 weight percent or more and about 10 weight percent or less based on the total weight of the resin composition, and
a weight of the acrylate is about 50 weight percent or more and about 80 weight percent or less based on the total weight of the resin composition.

18. The method for manufacturing an electronic apparatus of claim 13, wherein the resin composition comprises a polymeric polyol, and the polymeric polyol comprises at least one of polytetramethylene ether glycol or polypropylene glycol.

19. The method for manufacturing an electronic apparatus of claim 18, wherein a weight of the polymeric polyol is about 1 weight percent or more and about 10 weight percent or less based on the total weight of the resin composition.

20. The method for manufacturing an electronic apparatus of claim 13,
wherein the resin composition further comprises at least one of an organic catalyst, a plasticizer, an antioxidant, or a coupling agent,
the plasticizer comprises a material represented by any one of X-1 to X-5,
the antioxidant comprises a material represented by Y-1, and
the coupling agent comprises at least one of a silane-containing coupling agent or a phosphoric acid-containing coupling agent: 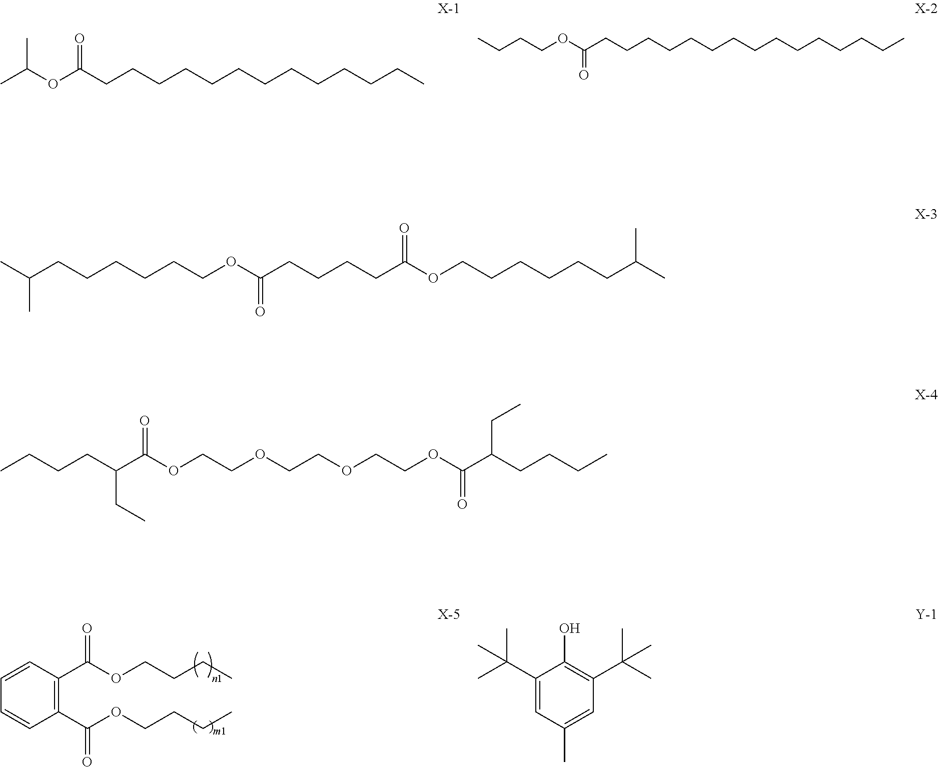
in X-5, n1 and ml are each independently an integer of 1 to 10.
